(19) United States
(12) Patent Application Publication
(10) Pub. No.: US 2003/0196680 A1
(43) Pub. Date: Oct. 23, 2003

(54) Process modules for transport polymerization of low epsilon thin films

(75) Inventors: Chung J. Lee, Fremont, CA (US); Oanh Nguyen, Union City, CA (US); Wei Shiang Charles Lee, Milpitas, CA (US); Michael Solomensky, Fremont, CA (US); Atul Kumar, Fremont, CA (US); James Yu Chung Chang, Cupertino, CA (US); Binh Nguyen, Cupertino, CA (US)

Correspondence Address: JACKSON WALKER LLP, 2435 NORTH CENTRAL EXPRESSWAY, SUITE 600, RICHARDSON, TX, 75080, US

(73) Assignee: DIELECTRIC SYSTEMS, INC, Freemont, CA (US)

(21) Appl. No.: 10/126,919

(22) Filed: Apr. 19, 2002

(51) Int. Cl. C23C 16/00; C25F 1/00

(52) U.S. Cl. 134/1.1; 118/719; 118/726; 438/905

(57) ABSTRACT

A Process Module (“PM”) is designed to facilitate Transport Polymerization (“TP”) of precursors that are useful for preparations of low Dielectric Constant (“∈”) films. The PM consists primarily of a Material Delivery System (“MDS”) with a high temperature Vapor Phase Controller (“VFC”), a TP Reactor, a Treatment Chamber, a Deposition Chamber and a Pumping System. The PM is designed to facilitate TP for new precursors and for film deposition and stabilization processes.

### BACKGROUND

This invention is related to a polymer deposition system that is useful for the fabrication of an integrated circuit (“IC”). In particular, this invention is related to Process Module (“PM”) used for deposition of low dielectric (“∈”) thin films. Furthermore, this invention discloses chemistries of precursor and methods for utilization of the PM to convert the precursor into dielectric thin film.

During the construction of ICs with shrinking device geometries, an increase in capacitance, mainly on the same layer of interconnects can result in unacceptable cross talk and resistance-capacitance (“RC”) delay. This RC delay has become a serious problem for ICs with feature size of less than 0.18 μm. Thus, the dielectric constant of the current insulation materials from which IC's are constructed must be decreased to meet the needs for fabrication of future ICs. In addition to dielectric and conducting layers, the “barrier layer” may include metals such as Ti, Ta, W, and Co and their nitrides and silicides, such as TiN, TaN, TaSixNy, TiSixNy, WNx, CoNx and CoSiNx. Ta is currently the most useful barrier layer material for the fabrication of IC's that currently use copper as conductor. The “cap-layer” or “etch-stop-layer” normally consists of dielectric materials such as SiC, SiN, SiON, SiyOx and its fluorinated silicon oxide (“FSG”), SiCOH, and SiCH. Thus, the new dielectric materials must also withstand many other manufacturing processes following their deposition onto a substrate.

Currently, there are two groups of low ∈ dielectric materials, which include a traditional inorganic group, exemplified by SiO₂, its fluorine doped product, FSG and its C & H doped products, SiOₓC_{y}H_{z} and newer organic polymers, exemplified by SiLK, from Dow Chemical Company. Chemical Vapor Deposition (“CVD”) and spin-on coating method have been used to deposit, respectively, the inorganic and polymer dielectric films. These current dielectric materials used in the manufacturing of the ICs have already proven to be inadequate in several ways for their continued use in mass production of the future IC's. For example, these materials have high dielectric constants (∈≧2.7), they have low yield (<5-7%) and marginal rigidity (Young's Modulus less than 4 GPa). In light of the shortcomings of current dielectric materials, a director of a major dielectric supplier has suggested that the use of thin films with high dielectric constants (e.g. ∈=3.5) will be extended to the current 130 nm devices (A. E. Brun, ”100 nm:The Undiscovered Country”, Semiconductor International, February 2000, p79). This statement suggests that the current dielectric thin films are at least four years behind the Semiconductor Industrial Association's (“SIA”) road map. The present lack of qualified low dielectric materials now threatens to derail the continued shrinkage of future IC's.

In addition to the above CVD and spin-on methods that used for the preparation of existing dielectric thin films, a Transport Polymerization (“TP”) process for deposition of a Poly(Para-Xylylene) (“PPX”) has been know for more than 30 years. However, the decomposition temperature (“Td”) of PPX was too low, and the dielectric constant of the resulting polymer (∈=3.2 to 2.7) was not low enough (Selbrede and Zucker, Proc. 3d Int. DUMIC Conference, 121-124, 1997). The Td of the thin film needs to withstand temperatures greater than 400° C. for future IC applications. Wang et al., Proc. 3d Int. DUMIC Conference, 125-128 (1997) reported that annealing a deposited layer of PPX increases the thermal stability, but even then, the subsequent loss of polymer was too great to be useful for future IC manufacturing. Wary et al. (Semiconductor International, June 1996, pp: 211-216) used the fluorinated dimer (e.g. cyclo-precursor ((α,α, α¹, α¹), tetrafluoro-di-p-xylylene) and a thermal TP process to make the “AF-4” of the structural formula: {—CF₂—C₆H₄—CF₂—}ₙ. AF-4 has a dielectric constant of 2.28 and has increased thermal stability comparing to PPX mentioned above. Under nitrogen atmosphere, AF-4 lost only 0.8% of its weight over 3 hours at 450° C. Note that all the above TP processes used dimers and the “Gorham Method” (Gorham et al., U.S. Pat. No. 3,342,754, 1967). These commercial or laboratory deposition systems used for TP of dimer primarily consist of (1) a vaporizer for the solid dimer, (2) a pyrolyzer to crack the dimer and (3) a deposition chamber as shown in the FIG. 1. U.S. Pat. No. 5,268,202 describes a “one chamber system” for transport polymerization of liquid monomers such as Dibromotetrafluor-p-xylene (“DBX”) and 1,4-bis-(trifluoromethyl) benzene (“TFB”). In their deposition system, both the pyrolyzer and the wafer are situated inside the same vacuum chamber. The system also utilizes a resistive heater to crack the DBX and TFB. Furthermore, all current pyrolyzers utilize metal parts that potentially leach out metal ions under high temperature (>600 to 800° C.). These metal ions result in metallic contamination of deposited thin films. Moreover, the precursor inlet and outlet ports are on the same end of the chamber, namely at the end opposite the end where the wafer is held. Further, the wafer is protected by a heat shield, which must be kept close to the heat source, and thus, is not ideally suited to act as a diffusion plate to ensure the even distribution of intermediates onto the wafer surface. Thus, deposition of precursors onto the wafer surface is not easily regulated and the thickness of dielectric films cannot be made constant over the entire wafer surface.

The current invention describes a process module (“PM”) for deposition of new dielectric materials with lower dielectric constant. This new PM is useful for deposition of low ∈ thin films for fabrications of future IC. In particular, this invention is related to a PM that is useful for transport polymerization using new precursor chemistries that are also revealed in this invention. The current invention avoids several problems that are encountered by existing CVD and TP processes. One aspect of the current invention pertains to a Process Module (“PM”) for a new deposition system that avoids several problems by cracking the precursor in one chamber and then transporting the intermediate molecules into a different deposition chamber. Further, the conditions of cracking can be adjusted to maximize the cracking of the precursor, ensuring that very little or no precursor is transported to the deposition chamber. Moreover, the concentration of the transported intermediates can be kept low, to avoid re-dimerization of intermediates. In addition, the current deposition system provides means to control the feed rate of precursor and substrate temperature, thus the resultant film properties are not available from using any of the existing deposition systems.

### BRIEF DESCRIPTION OF THE DRAWINGS

FIG. 1 shows the four main components of a deposition system for Transport Polymerization (“TP”);

FIG. 2 shows a process module consisting of a material delivery subsystem (201-05) that uses a high temperature vapor phase controller (“VPC”)(205), a transport polymerization reactor (210), a treatment chamber (265), a deposition chamber (220) and a pumping subsystem (262 & 280);

FIG. 3 shows a cross-section of the TP reactor that contains a cartridge heater (305), a thermal couple (310), a heater body (320), a heating shield (330), gas inlet (340) and outlet (350) and an insulation container (360) for the TP reactor;

FIG. 4 shows a 3D view of the heater body of the TP reactor that consists of 10 heating paths (410) and 5 mixing gaps (400) for mixing gas molecules;

FIG. 5 shows how the heater body (405) can be alternately constructed using multiple rows and columns of heater fins (430), preferably in alternating orientation.

FIG. 6A shows the designs for deposition chamber subsystem including its six major parts.

FIG. 6B shows the preferred deposition chamber subsystem of FIG. 6A with a tall cover and without a showerhead;

FIG. 7 shows a close up view between the ESC (620), pumping plate (630), wafer (710) and backside guard ring (700);

FIG. 8 shows a UV lamp located on the top of a pre- or post-treatment chamber;

FIG. 9 shows details of a post-treatment chamber, detailing structure 610 of FIG. 8;

FIG. 10 shows a schematic drawing that diagrams the configuration of the process module (“PM”) in relationship to a pretreatment module (“PT”) and transport module (“TM”);

FIG. 11 shows a step by step flow of a wafer through from a pre-selected slot of a loadport (“LP”) to the process module (“PM”) and back to the LP;

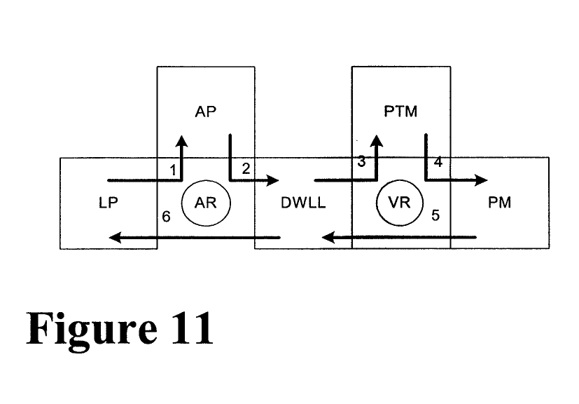

FIG. 12 shows a PM process control flow schematic, which shows the major components, valves and flow paths needed for PM process control;

FIG. 13 shows a PM process control flow schematic during wafer deposition, which represents the highlighted gas flow path through open valves during wafer deposition;

FIG. 14 shows a PM process control flow schematic during cleaning, which represents the highlighted gas flow path through open valves during the cleaning process;

FIG. 15 shows a PM process control flow schematic during a nitrogen purge, which represents the highlighted gas flow path through open valves during the nitrogen purge process;

FIG. 16 shows a PM process control flow schematic during a PM pump down, which represents the highlighted gas flow path through open valves during the PM pump down process;

FIG. 17 shows a PM process control flow schematic when the PM chamber is vented to the atmosphere, which represents the highlighted gas flow path through open valves during the venting of the PM chamber to the atmosphere;

### DETAILED DESCRIPTION OF PREFERRED EMBODIMENTS CONVENTIONAL CHEMICAL VAPOR DEPOSITION (“CVD”)

There are several fundamental differences between a transport polymerization (“TP”) process and a conventional Chemical Vapor Deposition (“CVD”) process. Additionally, there are distinctive differences in the Process Module (“PM”) described in the current invention when compared to the PM of a conventional CVD system.

A conventional CVD process begins when the starting chemicals are introduced into a traditional CVD chamber and are subjected to plasma or ozone to generate reacting intermediates. The CVD chamber is normally operated under sub-atmosphere pressure, or even moderate vacuum in the ranges of few mTorrs to few Torrs. A wafer is heated at high temperatures to remove any unstable products. A film grows not only the wafer surface but also on other surfaces inside a deposition chamber. Such non-selective deposition requires frequently cleaning for these surfaces inside the CVD chamber. Traditional CVD process that utilizes ozone is not suitable for making organic thin films. Traditional plasma CVD process that utilizes organo-siloxanes as precursor has produced useful dielectric films that have ∈ of about 2.7. However, all traditional CVD methods have failed to produce a dielectric material with dielectric constants (“∈”) lower than 2.7.

The plasma polymerization process has many inherent drawbacks. For example, feed chemical can produce different reacting species due to the non-selective cracking of chemical bonds by the plasma. Additionally, during plasma polymerization, free radicals, anions, and ions that contain various reactive sites on each intermediate will also be generated. Since these intermediates have different molecular orbital configurations, they will not react toward each other thus result networks of un-reacted chain ends. In addition, when more than 15 to 20 molar % of multi-functional intermediates consisting of more than two reactive sites are present inside chamber, most of these reactive sites will be trapped inside the polymer networks or become chain ends. Films with reactive sites have poor electrical properties and chemical stability without further post deposition treatment. Post deposition annealing is needed to eliminate these reactive chain ends and avoid later reactions of these reactive chain ends with undesirable chemicals such as water or oxygen.

Another drawback of plasma polymerization is the types of reactive intermediates that are produced. Plasma polymerization can produce many different kinds of reactive intermediates, including the very corrosive fluorine ions. When a substrate is heated to avoid condensation of the low molecular weight products, corrosive species and un-reacted impurities, corrosion of underlying metal such as a barrier metal on wafer can become a serious problem in the presence of corrosive species such as a fluorine ion.

Another shortcoming of a plasma process is the presence of many polymer chain-ends and pending short chains in polymer networks that result in high dielectric loss. The resulting dielectric may not be useful for high frequency (≧GHz) applications, which are critical to most future IC applications. Although chain ends may be reduced by increasing power levels such that the films contain a high cross-linked density, but a simultaneous high residual stress would also result.

Transport Polymerization (“TP”) Process Modules (“PM”)

While all conventional CVD processes have failed to make useful Ta-compatible thin films with a ∈<2.7, transport polymerization (“TP”) may become a primary approach for making useful low k films that are practical for fabrications of future ICs. Some of the important chemistries and mechanisms involved during TP has been reviewed previously (Chung Lee, “Transport Polymerization of Gaseous Intermediates and Polymer Crystals Growth” J. Macromol. Sci-Rev. Macromol. Chem., C16 (1), 79-127 (1977-78), pp79-127) and are hereby incorporated by reference.

In contrast to conventional CVD, transport polymerization (“TP”) employs known chemical processes to generate desirable reactive intermediates among other chemical species. Chemical processes that are particularly useful for this invention include photolysis and thermolysis. These two chemical processes can generate useful reactive intermediates such as carbenes, benzynes and other types of diradicals using appropriate precursors.

Photolysis can be accomplished by irradiation of compounds using electrons, UV or X-ray. However, high energetic electron and X-ray sources are expensive and typically not practical for reactors useful for this invention. When a UV photolytic process is used, a precursor that bears special leaving groups is normally required. For example, reactive intermediates such as carbenes and diradicals can be generated by the UV photolysis of precursors that bear ketene or diazo groups. However, these types of precursors normally are expensive and not practical to use due to their very unstable nature at ambient temperatures. Other precursors and chemistry have been used for generating reactive intermediates and discussed in prior art (C. J. Lee, “Transport Polymerization of Gaseous Intermediates and Polymer Crystals Growth” J. Macromol. Sci-Rev. Macromol. Chem., C16 (1), 79-127 (1977-78), pp79-127). However, most of these precursors are quite expensive to prepare and are not readily available, thus they are not desirable nor practical for IC fabrications outlined in the current invention.

Thermolysis has been used for TP of poly (Para-Xylylenes) (“PPX”) for the coating of circuit boards and other electronic components since early 1970s. Currently, all commercial PPX films are prepared by the Gorham method (Gorham et al., U.S. Pat. No. 3,342,754, the content of which is hereby incorporated by reference). The Gorham method employed dimer precursor (I) that cracks under high temperatures (e.g. 600 to 680° C.) to generate a reactive and gaseous diradical (II) under vacuum. When adsorbed onto cold solid surfaces, the diradical (II) polymerizes to form a polymer film (III).

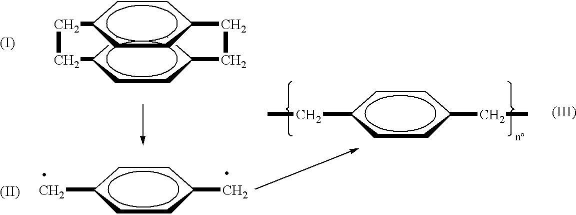

Since 1970, several commercialized products have appeared on the market with similar chemical structures. For example, a polymer PPX-D {—CH₂—C₆H₂Cl₂—CH₂—} had a dielectric constants, ∈ of 3.2. However, all these polymers were not thermally stable at temperatures higher than 300 to 350° C., and were not useful for fabrications of future ICs that require dielectric with lower ∈ and better thermal stability. On the other hand, the PPX-F,—(CF₂—C₆H₄—CF₂—)_{N} has a ∈=2.23 and is thermally stable up to 450° C. over 2.5 hours in vacuum. Therefore, rigorous attempts have been made to make PPX-F from dimer (—CF₂—C₆H₄—CF₂—)₂ (Wary et al, Proceedings, 2nd Intl. DUMIC, 1996 pp207-213; ibid, Semiconductor Int'l, 19(6), 1996, p211-216) using commercially available equipment. However, these efforts were abandoned due to high cost of the dimer and incompatibility of the barrier metal (e.g. Ta) with PPX-F films prepared by TP (Lu et al, J.Mater.Res.Vol,14(1), p246-250, 1999; Plano et al, MRS Symp.Proc.Vol.476, p213-218, 1998—these cited articles are herby incorporated by reference.)

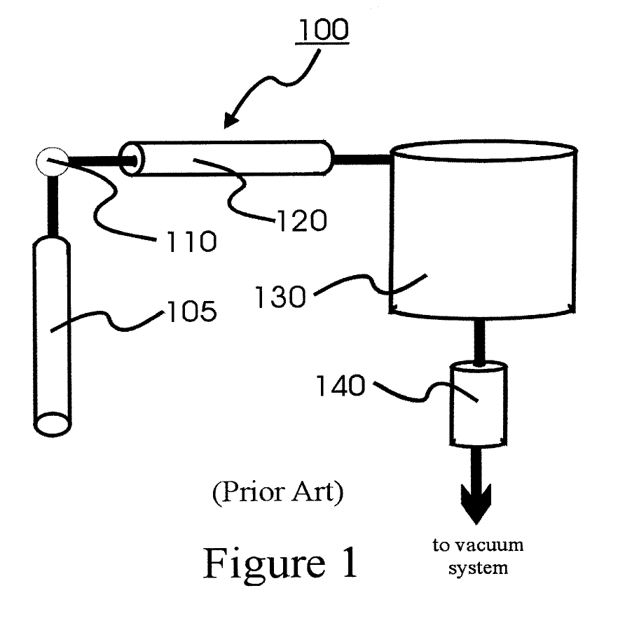

Many commercial process modules have been available for deposition of PPX since early 1970. These deposition systems comprise of primarily the same four main components, as shown in the prior art 100 in FIG. 1: a sample holder and material delivery system 105 is in fluid communication with the reactor 120 through a needle valve 110. The deposition chamber 130 is in fluid communication with the reactor 120 and the cold trap 140. Additionally, the entire system is connected to a vacuum system.

In these process modules, a resistive heater and a stainless steel reactor (i.e. pyrolyzer) is used to crack dimers. Additionally, a tubular quartz reactor has been used to crack the dimer (e.g. {—CH₂—C₆H₄—CH₂—}₂ as shown above in equation (I)), and used for making PPX-N (Wunderlich and associates (Wunderlich et al, Jour. Polymer. Sci. Polymer. Phys. Ed., Vol. 11, (1973), pp 2403-2411; ibid, Vol. 13, (1975), pp1925-1938). It is important to note that the PPX-N dimer (e.g. {—CH₂—C₆H₄—CH₂—}₂) bears no halogen, and thus there was no potential corrosion of the stainless steel reactor during preparation of PPX-N. In other words, a stainless steel pyrolyzer can only be used for a dimer that has halogens on a Sp²C carbon to make PPX-D ({—CH₂—C₆H₂Cl₂—CH₂—}, but it is not compatible with a precursor consisting of halogens on the Sp³C, for example, a precursor such as formula (IV) of the following:

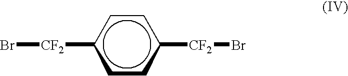

When (IV) is used, the iron inside the pyrolyzer's surfaces can react with the bromine if the temperature inside the pyrolyzer is higher than 420 to 450° C. The resulting iron bromide would contaminate the dielectric film and make it unsuitable for IC fabrications. Other shortcomings of commercial PM's are that they are not equipped with a proper deposition chamber for wafer or a vapor controller, which are important to the current invention. Thus, these commercial process modules are not useful for the present invention that uses halogen-containing precursors.

The U.S. Pat. No. 5,268,202 with Moore listed as inventor (“the Moore '202 patent”), teaches that a dibromo-monomer (e.g. IV={Br—CF₂—C₆Cl₄—CF₂—Br}) and a metallic “catalyst” (Cu or Zn) inside a stainless steel pyrolyzer can be used to generate reactive free radical (V) according to the reaction (3). However, to lower the cost of starting materials, a large proportion (>85 to 95 molar %) of a more readily available co-monomer with structure {CF₃—C₆H₄—CF₃} has also been used to make PPX-F.

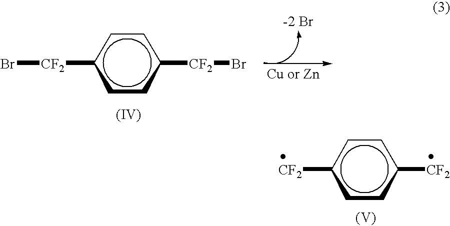

There are several key points that need to be addressed concerning the usage of the monomer (IV) in reaction (3). First, an earlier U.S. Pat. No. 3,268,599 (“the Chow '599 patent”) with Chow listed as inventor, revealed the chemistry to prepare a dimmer as early as 1966. However, the Chow '599 patent only taught the method to prepared dimer {CF₂—C₆H₄—CF₂}₂ by trapping the diradical (V) in a solvent. Furthermore, the equipment and processing methods of the Chow '599 patent employed were not suitable for making thin films that are useful for IC fabrications. Second, according to the Moore '202 patent, the above reaction (3) would need a cracking temperature ranging from 660-680° C., without using the “catalysts”. However, we found that metallic “catalysts” such as Zn or Cu would readily react with organic bromine at temperatures ranging from 300 to 450° C., the pyrolyzer temperatures employed by the Moore '202 patent. Formation of metallic halides on surfaces of these “catalysts” would quickly deactivate these “catalysts” and inhibit further de-bromination shown in reaction (3). In addition, the presence of Zn and Cu halides inside a pyrolyzer would likely cause contamination for the process module and dielectric films on wafer. Third, cooling of reactive intermediate and wafer cooling could not be efficient because both the wafer holder and pyrolyzer were located inside a close system for the deposition chamber that was used in the Moore '202 patent. Consequently, the process module used by the Moore '202 patent cannot be useful for preparation of thin films of this invention.

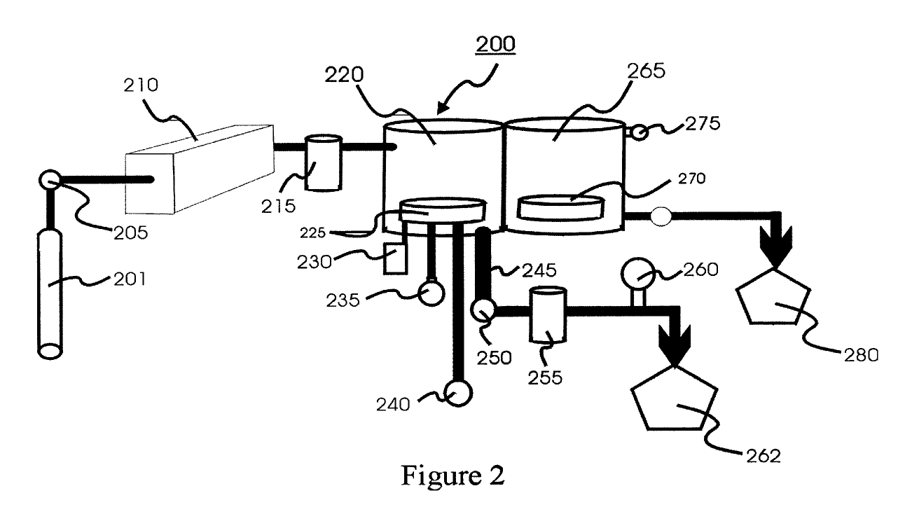

The schematic drawing in FIG. 2 shows a Process Module (“PM”) of the current invention consisting of a Material Delivery Subsystem (“MDS”) that uses of a high temperature vapor flow controller (“VFC”) 205, a TP Reactor 210, a deposition chamber 220 and a post-treatment chamber 265 that may also be used for pre-treatment, and a pumping system 262 and 280. When this PM is used with the liquid precursors described in the current invention, a useful method of dielectric film deposition can be achieved without the limitations of either the Moore '202 or Chow '599 patent, as described above. Other components shown in FIG. 2 comprise: 215 TP-trap as an option; 225—ESC/base plate/lifting pins/cooling plate/thermocouple; 230—chiller with coolant; 235—helium flow meter and pressure gauge; 240—lifting pins and motor control; 245—heated tube; 250—throttle valve; 255—Pump trap as another option; 260—Pressure gauge; 270—wafer chuck; 275—pressure gauge. These components are discussed in more detail below.

The Process Module (“PM”) of this invention is used to prepare dielectric films that are made from a large number of long polymer chains. In order to deposit these films, a liquid precursor is heated in a stainless container to a consistent temperature. The precursor is fed into a gas reactor through a vapor flow controller (“VFC”) 205, as shown in FIG. 2. The gas reactor 210 splits the precursors into reactive intermediates that bear two unpaired electrons, or diradicals, in addition to other side products. These diradicals are very reactive, and polymerize immediately when they collide with each other on a solid substrate. This polymerization occurs even when the substrate temperature is very low (e.g. as low as −100° C.). In contrast, under low vapor pressure (e.g. few mTorrs), the diradicals do not adsorb on a substrate that has a higher temperature (e.g. greater than 20° C. to 25° C.), and no film growth would be expected under such conditions. However, in the gas phase, “hot” diradicals may collide with each other and form crystalline “dimers”. Therefore, it is important to keep the partial pressure of the immediate sufficiently low to avoid the dimer formation.

All reaction products are transported from the reactor to the deposition chamber by diffusion process. A Transport Polymerization (“TP”) trap is an option to separate the useful diradicals intermediates from all other undesirable reaction products that diffuse from the reactor into the deposition chamber. Another optional embodiment of the deposition chamber includes a showerhead that is placed over the wafer to enhance uniform film deposition on wafer. In addition, a low temperature electrostatic chuck (“ESC”) is also used to control the deposition rate (“DR”) and thickness uniformity of deposited films. The DR of a film is controlled primarily by the wafer temperature and the feed rate (“FR”) of the precursors via the VFC. To maintain uniform temperature over the wafer, the backside of the wafer is filled with Helium (“He”) that is kept under a pressure of at least three Torrs. A diploar ESC is operated under +/−250 to 300 Volts to acquire sufficient static charge for holding the wafer. Under these conditions the temperature will uniformity be in the range of +/−0.5° C. over the whole wafer if the leak rate of the He is less than 0.3 to 0.4 square centimeters (“sccm”). At wafer temperatures of lower than −25° C., most diradicals are readily adsorbed onto wafer and polymerized. The remaining reaction products from the gas reactor are generally not reactive toward the diradicals at low temperatures, and are pumped away through a throttle valve, a turbo pump, and a mechanical pump into the exhaust system.

Although the above description of the PM presents a general description of the current invention, the PM described will only be useful for fabrication of future ICs if it can meet special requirements, which are not found in other PM's used in conventional CVD systems. The details of each of the new main components are discussed below.

Material Delivery Subsystem (“MDS”)

The purpose of the feed control component is to deliver a stable flow of precursor chemicals into the TP reactor, and a minimum threshold performance is required. The MDS consists of a sample holder with a heater and a feed control component. The chemicals can be delivered as liquid, or preferably gas. When the precursor is liquid, a liquid sample holder (e.g. component 201 in FIG. 2) should be made from non-corrosive materials. These non-corrosive materials include Pyrex glass, stainless steel, ceramic quartz, or other material that can be heated from room temperature to 150° C., and is strong enough two withstand a vacuum (<5 to 10 mTorrs). The temperature of the sample holder 201 should be controlled during deposition so that feed rate can be easily controlled to within +/−2 to 2.5° C., preferably within +/−0.5 to 1.0° C. The feed rate can be controlled using a liquid mass flow meter (“LMFC”) 205 or preferably, a high temperature vapor flow controller (“VFC”), 205. A liquid precursor from the container is forced through the LMFC by pressure or by pumping. The liquid precursor is then vaporized either in a separate vaporizer or in the TP Reactor, 210. The LMFC should deliver from 50 to 200 mg per minute for a 200 mm wafer, preferably 150 to 500 mg per minute of precursors used for this invention. A commercial LMFC consisting of Polyimide membrane will degrade when exposed to precursors of this invention thus it is not useful for this invention. A LMFC consists of non-corrosive, metallic membrane, and is calibrated using precursors of this invention can be used for this invention. The LMFC needs to deliver at least +/−2.5%, preferably 1.5% accuracy by mass at temperatures ranging from 25 to 150° C. We found no commercial LMFC's that were useful for this invention, due to an inadequate feed rate control.

When the VFC, 205, is used to deliver the precursor material, the liquid precursor in the sample holder is heated and vaporized under vacuum with the feed rate controlled by the VFC. In a preferred embodiment of this invention, a high temperature VFC is used. The VFC needs to capable of delivering from 3 to 10 sccm of precursor material when 200 mm wafer is used and 6 to 20 sccm when a 300 mm wafer is used. The VFC should be functional at vapor temperature ranging from 40 to 200° C., and preferably from 80 to 150° C.

When the precursors are solid, quantitative delivery of vapor precursor needs more elaborate and more expensive commercial equipment. This type of equipment has been commonly used in chemical vapor deposition systems using metal organic compounds (“MOCVD”) processes that have been available for many years. However, well developed processing conditions and calibrations are needed to extend pot life for each solid precursor that is constantly under heating.

The preferred designs of the MDS for the present invention include a liquid precursor that is stored in a stainless container manufactured (e.g. 201) by Schumacher Inc. The container has two ¼″ manual valves with VCR connectors. The lower-level valve is the inlet where the tube goes to the bottom of the container. The higher-level valve is the outlet where the precursor vapor exits the container. The container is surrounded by heating tapes and has a temperature sensor. The precursor temperature (“Tp”) setting is predetermined to provide 0.3 Torr, preferably 1 Torr of vapor pressure. Only the outlet valve is open during normal operation.

In a preferred embodiment, the precursor vapor enters a ½″ stainless tube that splits into two lines: one leads to the mechanical pump; and other leads to the VFC through a pneumatic valve. The gas lines are heated independently and the line temperature (“T_{L}”) should be 2° C., preferably 5° C., higher than that of the Tp to prevent condensation in this section of the gas lines. In addition, the temperature setting for VFC (“T_{vfc}”) should be at least 2 to 5° C. higher than the T_{L} to prevent condensation in the VFC. During refilling of precursor, the gas line to pump is evacuated to remove residual gas before VFC. When the precursor liquid level is low, the liquid sensor on the container should give a low-level warning.

The high temperature VFC consists of 3 major parts: a control valve with adjustable opening at the entrance; an open volume with a precision pressure sensor (up to 20 Torrs, with 0.15% accuracy); and a small orifice at the exit. A specially designed VFC for this invention is provided by MKS Inc. An on-board computer measures the pressure in the open volume, and adjusts the control valve to keep the pressure to a preset value. The flow rate through the small orifice increases with increasing pressure (i.e. the pressure increase is almost linear when there is a large pressure drop across the orifice, Pᵢₙ>2Pₒᵤₜ). A consistent pressure would ensure a consistent flow rate. The VFC controls the flow rate accurately at low pressure (around 1 Torr). The operating principle of VFC is different from that of a mass flow controller, which controls the flow at high pressure (around 1000 Torr).

There are two gas-lines each with a control valve after VFC: one lead to the pump to force out precursor in case the VFC is flooded with precursor. The other gas line leads to the TP Reactor. The line temperature should be at least 2° C., preferably 5° C., higher than that of the T_{VFC}.

The TP Reactor

Instead of using a conventional tubular stainless steel pyrolyzer, the preferred embodiment of the present invention requires a specially designed TP Reactor that facilitates new precursor chemistries and deposition processes used to prepare low ∈ thin films. The TP Reactor needs to generate useful reactive intermediates with high efficiency and low side-reaction product from precursors that have a general chemical structure as shown in formula (VI).

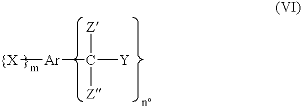

wherein, n° or m are individually zero or an integer, and (n°+m) comprises an integer of at least 2 but no more than a total number of sp²C—X substitution on the aromatic-group-moiety (“Ar”). Ar is an aromatic or a fluorinated-aromatic group moiety. Z′ and Z″ are similar or different, and individually a hydrogen, a fluorine, an alkyl group, a fluorinated alkyl group, a phenyl group or a fluorinated phenyl group. X is a leaving group, and individually a —COOH, —I, —NR₂, —N⁺R₃, —SR, —SO₂R, wherein R is an alkyl, a fluorinated alkyl, aromatic or fluorinated aromatic group, and Y is a leaving group, and individually a —Cl, —Br, —I, —NR₂, —N⁺R₃, —SR, —SO₂R, or —OR, wherein R is an alkyl, a fluorinated alkyl, aromatic or fluorinated aromatic group. Furthermore, the aromatic is preferably a fluorinated aromatic moiety including, but not limiting to, the phenyl moiety, —C₆H₄₋ₙFₙ (n=0 to 4) such as —C₆H₄— and —C₆F₄—; the naphthenyl moiety, —C₁₀H₆₋ₙFₙ—(n=0 to 6) such as —C₁₀H₆— and —C₁₀F₆—; the di-phenyl moiety, —C₁₂H₈₋ₙFₙ— (n=0 to 8) such as —C₆H₂F₂—C₆H₂F₂— and —C₆F₄—C₆H4—; the anthracenyl moiety, —C₁₂H₈₋ₙFₙ; the phenanthrenyl moiety, —C₁₄H₈₋ₙFₙ—; the pyrenyl moiety, —C₁₆H₈₋ₙFₙ— and more complex combinations of the phenyl and naphthenyl moieties, —C₁₆H₁₀₋ₙFₙ—. Note that isomers of various fluorine substitutions on the aromatic moieties are also included in this invention.

The functional requirements for a TP Reactor are largely determined by chemical structure of leaving groups X and Y and chemical methods that used to remove them in reactor. The leaving groups can be removed from precursors of formula (VI) by several different chemical methods. The methods that generate reactive intermediates under vacuum or under inert atmosphere include, but are not limited to:

irradiation using photons or electrons

cracking using thermal heat,

plasma energy, or

microwave energy

In order for a TP Reactor to be useful for this invention, it must generate useful reactive intermediates with high efficiency and have low side reaction products. In essence, the TP Reactor temperature should be closely controlled and the temperature inside the reactor should be uniform versus the flow direction so that only desirable chemical reactions can take place. We found that tubular pyrolyzers that are used in commercial process modules do not meet critical temperature requirements for TP Reactor of this invention. For example, when a tubular pyrolyzer that was 8 inch long and 1.2 inch diameter was heated at 480° C. under 10 mTorrs vacuum, only a small region of the inner wall in the down stream areas reached the desirable 480° C., which was due to poor heat conduction under vacuum. Results from calculations indicated that a large volume inside the pyrolyzer was at temperature far below 480° C. Thus, a tubular reactor does not satisfy the required high efficiency (>99.99%) for removing Br from a precursor of formula (IV) wherein, Y═Br, and the bond energy (“BE”) of the sp³Cα—Br bond equals 58 Kcal/Mole under few mTorrs. In fact, under such a condition, a majority of precursor material would pass through the tubular pyrolyzer without removal of Bromine.

One alternative is to increase the pyrolyzer temperature to 680° C. or higher. At these higher temperatures, the inside temperatures of the pyrolyzer may achieve complete removal of Bromine from the precursor of formula (IV) (wherein Y═Br). However, at such high temperatures (e.g. ≧680° C.), some of the sp²C—H and sp³C—C bonds of the precursor (IV) and intermediates (V) respectively would also be broken. These undesirable reactions would result in formation of multi-functional (>2) radicals and “coke” formation inside the pyrolyzer. The resultant formation of a thick carbon deposit inside the pyrolyzer would further insulate heat conduction to the center region of the pyrolyzer, and would make the pyrolyzer even less effective. In addition, the multi-functional radicals would result in dielectric films consisting of many polymer chain ends. Thus, the resulting films produced in tubular pyrolyzers have poorer thermal stability and inferior electrical properties.

The problems associated with a precursor of formula (IV) (wherein Y═Br) will not occur when conventional dimers are employed. These conventional dimers (e.g. formula (I)) have a high ring strain energy (“Eᵣₛ”) of about 31 Kcal/mole due to presence of two bulky benzene rings. The ring strain energy, in principle would lower the BE (76 Kcal/mole) of the sp³Cα-sp³C bonds in the dimers to bonding energy of a leaving group (“BE_{L}”)=76 Kcal/mole minus 31 Kcal/mole, or BE_{L}=45 Kcal/mole and reduce the required temperatures for a tubular pyrolyzer. It is important to note that the next weakest bond in the dimer is the sp³Cα—H bond that has a bonding energy of a core group (“BE_{C}”) of about 88 kcal/mole, or a dimmer bond energy (“dBE”)=(BE)_{C}—(BE)_{L}=(88-45) or 43 Kcal/mole higher than that of the sp³Cα-sp³C bonds in the dimer. Therefore, under normal recommend pyrolyzer temperatures ranging from 620 to 640° C., the tubular pyrolyzer could provide a near 100% efficiency without apparent coke formation. However, under the identical pyrolyzer temperatures and vacuum conditions, a precursor such as in formula (IV) (wherein Y═Br), generate a large portion of un-reacted precursors that would form a thin film that is useless for IC fabrications.

In short, having a precursor that comprises of an appropriate designed chemical structure and leaving groups is only a necessary first step, but not sufficient for making thin films that are useful for fabrications of future ICs. In addition, a properly designed TP Reactor is needed. Accordingly, design requirements for TP Reactors will be different for desirable precursors that have different chemical structures and leaving groups. When precursors employed for the current invention meet specific criteria, a proper TP Reactor can then be designed accordingly.

Although not wanting to be bound by theory, the bonding energy for a leaving group (BE)_{L} needs to be less than 65 to 70 Kcal/Mole. However, exceptions for this general rule can be found. For example, the ring-strained dimer of formula (I) as mentioned above. Additionally, the thermal removal of a desirable leaving group (e.g. carboxylic group) can occur at temperatures as low as 200 to 250° C. under ambient, and 300 to 400° C. under vacuum. This thermal pyrolysis could occur readily when the carboxylic is in its salt or ionic form, or when its resonant energy can lower the bonding energy of the carboxylic group. In addition, the (BE)_{L} should be at least 25 to 30 Kcal/Mole, preferably 30-40 Kcal/Mole, lower than bonding energy of the 2nd weakest chemical bond that presented in the precursor. For instances, for precursor with formula (IV) (wherein, m=0, n=2 and Y═Br), the BE for the leaving group is (“BE_{L}”)=58 Kcal/Mole, thus Z can be —F ((BE)_{C}=96 Kcal/Mole) and —Ar— can be {—C₆H₄—}. For such a precursor, the dBE is 38 Kcal/Mole, herein dBE=(BE)_{C}—(BE)_{L}. When this precursor is used, the maximum temperature variation across to the gas diffusion direction, (“dTr”) inside the TP Reactor can be as high as 150° C. to 190° C., and preferably no more than 120° C. to 130° C. When a TP Reactor had a dTr larger than 150° C. to 190° C., the resultant films contained impure chemicals that would result if the reactor temperature were too low. Coke formation would occur when a high reactor temperature was used and carbon would degrade the TP Reactor very shortly after deposition.

Although not wanting to be bound by theory, the maximum allowed temperature variation (as expressed in ° C.) inside the TP Reactor should be equal to or less than 5 times, preferably 3 to 4 times, of the dBE in Kcal/Mole (i.e. “dTr≦5*dBE”). However, precursors with desirable chemical structures and leaving groups are often not available due to limited available synthetic schemes and starting materials, a TP Reactor with lower dTr will allow choices for using precursors that have smaller dBE. For example, when inside reactor temperature can be controlled to ±35° C., then precursors of formula (VI) that have m=n=1, Y═Br and I, X═Br and I and Z═F can be useful for this invention.

The preferred TP Reactor design of the current invention will incorporate the chemical properties of the precursor material. For example, the gas reactor will break up the selected precursors into intermediates and other side products at low pressure. The inside of the reactor is made of high purity materials that are inert to the chemical reactions of the selected precursors and their intermediates. The reactor relies on thermal energy (i.e. temperature) to carry out the reactions. Furthermore, the preferred reactor requires re-activation or cleaning after a specified period of film depositions, which can be accomplished by burning the organic residues inside the reactor in the presence of oxygen. Wherein, oxygen or air is fed through a mass flow controller (“MFC”) and a valve into the reactor. The resulting combustion products (mainly CO, CO₂, H₂O and other small organic compounds) can be pumped directly to the exhaust through the reactor by-pass line and valve. Accordingly, a TP Reactor has an inlet for precursor and an outlet for reaction products that generated from the reactor. In addition, the outlet also has a bypass for injection of oxygen during cleaning and its inlet has a bypass for exhaust of combustion products.

In a preferred embodiment of this invention, a thermal or photo-assisted thermal cracking process is employed to generate useful reactive intermediates from precursors described in the above. Therefore, a TP Thermal Reactor is comprised of a heater and an inside heater body for heating the precursor and an outside container for keeping the inside heater body under vacuum condition. Details of the material selection, heating methods, and heater body designs are discussed below.

Material Selections: The preferred materials selected for the container wall of the TP Reactor are selected and manufactured from one of a group of materials including, but not limited to quartz, sapphires or Pyrex glass, Alumina Carbide, Al₂O₃, surface fluorinated Al₂O₃, Silicon Carbide, Silicon Nitride. These conductive materials are resistant to halogen corrosion at temperatures as high as 680° C. When a container wall is a metallic material, the inside wall of the metallic container needed to be coated with one of the above ceramic material to prevent corrosion. The heater body can be constructed from these ceramic media with pores, small tubes, heating fins or spherical balls.

Heating Methods: The TP reactor can be heated by several methods. However, in preferred embodiments of the present invention, a resistive heater, and an infrared (“IR”) heater are used. When a resistive heater is used, the inside heater body has physical contact(s) with inside wall of the TP Reactor. The inside heater body is heated primarily via conductance and some radiation. In this case, the heater body needs to have excellent thermal conductivity to maintain uniform temperature inside a vacuum. Without a proper design to take advantage of the radiation effect, the inside heater body will have high temperature variation especially if the heater body has poor conductivity.

An IR heater can be used to heat the heater body. Tungsten Halogen lamps are part of a preferred embodiment for an IR heater of the current invention. When an IR heater is utilized, the wall of TP Reactor should use an IR transparent material (e.g. quartz), so that IR can reach the inside heater body. Preferably, the inside heater body is an IR absorbing material such as Silicon carbide, Alumina carbide or Alumina Oxide etc. The heater body consists of heater elements that can be a porous medium, small tubes, fins or spherical balls. These IR adsorbing elements can be placed as continuous media or be spaced inside the reactor, thus create an alternating heating and mixing zones inside the reactor. This type of reactor can generate more uniform heating for passing precursors and prevent back diffusion for intermediates. When an employed precursor exhibits strong absorption in the IR ranges for its leaving groups such as halogen and carboxylic acid, the reactor efficiency can be enhanced by photon-assisted thermal cracking.

Alternatively, a resist heater can be used to heat a black body such as silicon carbide so the black body can generate IR in the ranges from 700 to 1200 cm⁻¹. In conjunction, the outside wall of the TP Reactor should be constructed using an IR transparent material so that radiation can reach the inside of the TP Reactor.

As an alternative, the outside wall of the TP Reactor can also be constructed using a material that is not transparent to IR. For instance, the resist heater can be mounted directly onto the wall of the TP Reactor, while a black body such as SiC is inserted inside the TP Reactor. In this case, the black body inside the TP Reactor is heated to generate IR in the ranges from 700 to 1200 cm⁻¹. Thus, the precursor vapor can be heated by the IR radiation inside the reactor.

Heater Body and Designs: The heater body and design of the TP Reactor can be in any shape or configuration as long as its temperature variation, dTr meets the requirements mentioned in the above. In principle, the required TP Reactor temperature decreases as the resident time or/and the collision increases under a given feed rate for a given precursor. In general, under a given feed rate, the resident time increases with increases in volume of the reactor. To avoid using high reactor temperatures and large reactor volume, the numbers of collision between precursors and inside heater body can be maximized by increasing the surface area of the inside heater body. Accordingly, under a vacuum of 20-100 mTorr ranges, when the TP Reactor is less than 40 cm³, preferably 20 cm³, the surface area of the heater body is at least 300 cm², preferably 500 cm². The surface areas of the inside heater body can be adjusted by using a porous medium, small tubes, heating fins or spherical balls.

Although not wanting to be bound by theory, to maximize heat transfer from collision of precursor with the heater elements, a reactor body should be constructed from a porous medium. In principle, the inside diameter of these open pores should be less than the mean free path (“MFP”) of the selected precursors. A preferred TP Reactor will consists of large number of small pores that can be fabricated from ceramic such as, Al₂O₃, Alumina Carbide, surface fluorinated Al₂O₃, Silicon Carbide and Silicon Nitride. Alumina carbide and SiC are good IR adsorbing materials. The ideal porous medium should have a skeletal structure and the skeletal wall that consists of no void, no inclusion, and no entrapment or metallic impurity. The porous medium is particularly useful for this invention if it has reticular structure of open, duode-cahedronal-shaped cells connected by continuous solid ceramic ligaments. Its matrix of cells and ligaments are completely repeatable, regular and uniform throughout the entirety of the medium. These porous media have good thermal conductivity and structure integrity. It is rigid, highly porous and permeable and has a controlled density or ceramic per unit volume. Density of useful media for this invention varies from 5 to 90%, preferably from 30 to 50% for a combination of high permeability and thermal conductivity. Cell size can be from 5 to 150, preferably from 20 to 60 pores per inch (“ppi”) with a mean pore size from 5 mm to 0.12 mm, preferably from 1 to 0.3 mm. These porous media have high surface areas to volume ratio ranging from 10 to 80 cm²/cm³, thus compact reactors be fabricated for this invention. Porous alumina carbide, alumina and silicon carbide provided by Pyrotech Inc., and are useful for this invention. Porous reactor of monolithic entity that has a low heat-contact resistance between its heating element and heating body porous ceramic) are useful for this invention.

The reactor body can also be constructed from small tubes or honeycomb with 0.1 to 5 mm, preferably 0.5 to 3 mm inside diameter (“Φi”). In principles, when the Φi of the small tube is less than the mean-free-path (“MFP”) of the precursors, more collision between the precursors and inside surfaces of the reactor can be expected. An engineer with average skill in the art can calculate the MFP, and no additional description should be needed here. Thus, when a multiple-zone reactor is used, the heater bodies in the gas entrance region should consist of smaller holes, whereas the gas exit region should use larger holes. To prevent intermediates from gas collision and achieving sufficient feed rate, Φi should be equal or 2 to 3 times higher than the MFP in gas exit region. The TP Reactor consists of large number of smaller tubes can be fabricated from ceramic such as, Al₂O₃, surface fluorinated Al₂O₃, Silicon Carbide, Silicon Nitride and Aluminum Nitride. Ceramic Honeycomb and Cordierite that are provided by Rauschert Technical Ceramics Inc.

Although not wanting to be bound by theory, an alternate design of a TP Reactor will include a design that creates turbulent flow to increase collision between gaseous precursors and inner surfaces of a reactor. An especially useful TP Reactor of this invention is constructed that will use only a small volume and high inside surface area, thus will not require excess reactor temperatures that result in undesirable films for future IC applications.

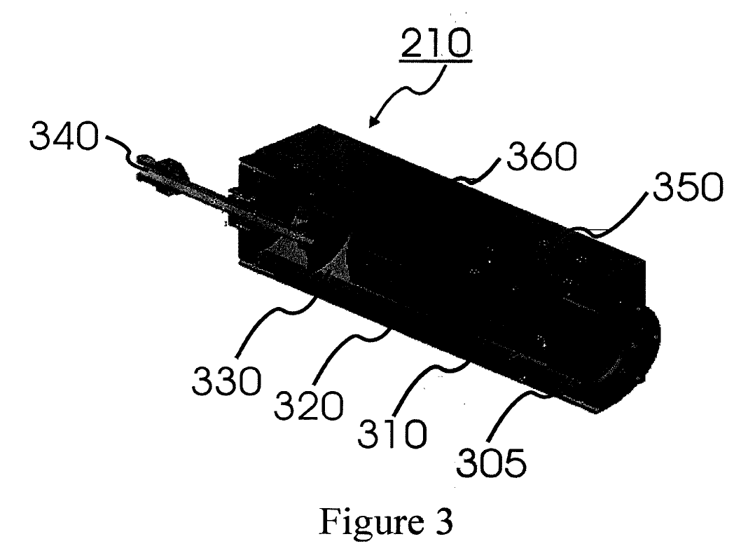

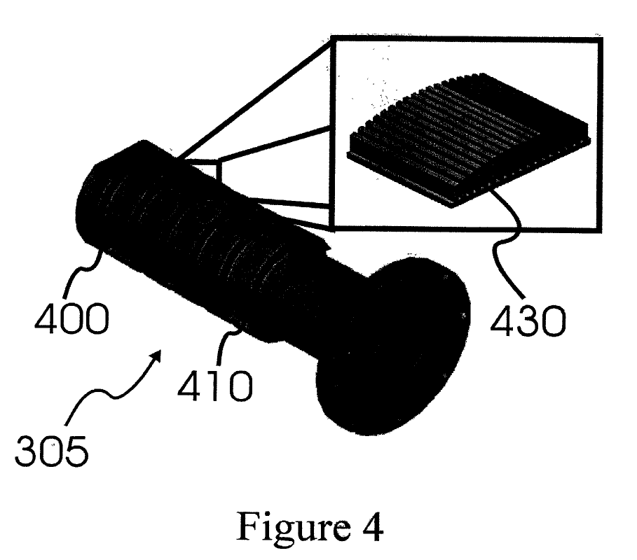

An example of a useful TP Reactor is shown in FIGS. 3 and 4. These TP Reactors consist of multiple zones of alternating heating fins and mixing zone that are in spiral orientation.

FIG. 3 shows a cross-section of the TP Reactor 210 that consists of a cartridge heater 305, a thermal couple 310, a heater body 320, a heating shield 330, gas inlet 340 and outlet 350 and an insulation container 360 for the reactor. A heat shield 330 is closely contacted with the heater body to achieve better conversion of precursors without over heating. It is preferred to keep the heat shield at least 120° C., preferably within 20° C. of the heater temperature. It is also preferred to keep the heat shield at least 300 to 750 μm away from inside wall of the insulation container.

FIG. 4 shows a 3-dimensional (“3-D”) view of a preferred heater body that consists of 10 heating paths 410 and 5 mixing gaps 400 for mixing gas molecules. In order to create turbulent flow for gas molecules, the heating paths are not aligned in straight line but in spiral orientation. The heating paths have shallow gaps of ¼″ deep and is ½″ wide on a ¾″ standoff on the heater body. The mixing gap can be ½″ deep and ½″ wide on a 2 ½″ heater body. Furthermore, at the heating paths, multiple heating fins 430 can be constructed to increase the heating efficiency. The heating fins are preferably spaced at distance that is less than the MFP of the gas in the heating regions. Ideally, the space between heating fins at entrance region of the reactor will be smaller than the MFP to increase collision of precursors. The space of heating fins at exit region will be larger than MFP in order to decrease gas pressure and reduce gas phase collision and powder formation.

This design ensures multiple collisions between gas molecules and the inside surfaces of the reactor. This design tends to equalize the number of collisions for all gas molecules that passing through the TP Reactor, thus provides complete chemical conversion with less danger of overheating the precursors, and having less “coke” formation.

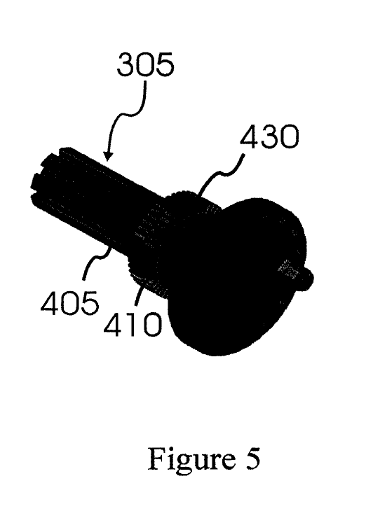

Alternatively, the heater body can be constructed using multiple rows and columns of heater fins, preferably in alternating orientation as shown in FIG. 5. Ideally, the space between heating fins at entrance region of the reactor will be smaller than the MFP to increase collision of precursor. The space of heating fins in an existing region will be larger than MFP in order to decrease gas pressure and reduce gas phase collision and powder formation.

A random flow of precursor gas inside the heater body can be constructed from the closet packing of spherical balls. The diameter of the spherical balls ranges from 0.1 mm to 10 mm, preferably from 2 to 7 mm. Ceramic spherical balls are preferred. When an IR adsorbing ceramic material such as SiC and Alumina Carbide is used, the outside wall of the TP Reactor needs to be IR transparent. Alternatively, a resist heater can be used in conjunction with a ceramic reactor with an outside wall made form heat conducting ceramic and alumina balls as heater body.

In preferred embodiments of the present invention, there are at least two distinctly different heater configurations that can be used to heat the reactor. First, the heating can be uniformly applied to the whole heater at one heater temperature. The precursors inside the reactor will gradually increase their temperatures in the transport direction. Although not wanting to be bound by theory, in this case, a phenomenon known as back diffusion of the reactive intermediates inside the reactor will lead to coke formation during long exposure of such intermediates to the high temperature. One method to prevent the back diffusion is to reduce the reactor volume, which will increase the flow rate of the gas chemicals inside the reactor. For example, using porous heater element can accomplish a reduction in reactor volume, if the surface area inside the reactor is very large. Consequently, porous heater elements often cannot provide sufficient heat transfer, and un-reacted precursors appear after reaction time is extended over certain period.

Although not wanting to be bound by theory, the appearance of un-reacted precursors may be the result of a cooling effect from incoming precursors that are normally several hundred degrees below the heater temperature. One way to avoid a cooling effect from occurring is to utilize two-zone heaters. For example, a pre-heater can be used to heat the precursors to temperature below its cracking temperature, which limits the conversion of precursors into reactive intermediates. However, once the precursors in the pre-heater reach a desirable temperature (e.g. 300 to 350° C.) or pressure (P=NRT/V), the pre-heated precursors can then be quickly released into the second-zone for thermolytic reaction. The utilization of a two-zone heating design in a TP reactor can avoid excess carbon formation inside the reactor.

The Reactor Cleaning Subsystem (“RCS”)

Because all thermal TP Reactors need periodic cleaning to remove residual organic chemicals that become trapped inside the reactor, a TP Reactor needs to be equipped with a Reactor Cleaning Subsystem (“RCS”). The preferred RCS of the current invention is connected to the reactor and is by-passed to a sewage deposit tank or gas scrubber system. There are many different methods can be used to clean TP Reactor that contains organic residuals, some of these methods are:

i. A RCS can consist of a steam boiler and a pressurized nitrogen supply. The steam boiler can generate up to 1-5 psi, preferably from 5 to 10 psi of steam. The nitrogen pressure can be as high as 5 to 20 psi, or preferably 20 to 50 psi.

ii. A RCS can consist of a simple hot air blower or a oxygen tank. To clean the black carbon or organic residues inside the reactor 1-5 psi, or preferably from 5 to 20 psi of hot air or oxygen is injected into the reactor at high temperatures. The air or oxygen temperature should be within 200° C., and preferably within 100° C. of the reactor temperatures to prevent thermal shock and cracking of heater elements inside the reactor. This is especially important if the heater elements are made of ceramic or porous ceramic.

iii. Alternatively, a ceramic reactor can be also cleaned using oxidative plasma.

It is important to note that the examples of the RCS systems are for a single deposition chamber for a single TP Reactor. One skilled in the art will appreciate that the design principles for the TR Reactor can be easily applied to industrial cluster tools that have multi-deposition chambers.

Additionally, to prevent film deposition inside the gas line between the TP Reactor and the deposition chamber, the gas line and chamber wall temperatures should be at least 25 to 30° C., preferably 30 to 50° C.

The TP Trap

An optional component or part of the present invention is a TP Trap that can be installed in between the TP Reactor and the Deposition Chamber. The TP trap can be utilized to trap leaving groups or other undesirable chemicals generated from TP Reactor. A TP Trap can be omitted, if Carbon Dioxide or hydrogen is the leaving group, such as (IV, X=COOH, m=1 or 2). A TP Trap is normally kept at temperatures as low as possible but at least equal to or higher than the ceiling temperatures (“T_{CL}”) for the reactive intermediates if possible. The T_{CL} is the upper limiting temperature that an intermediate can be adsorbed and grow into film. When the leaving group has a melting temperature (“Tₘ”), effective trapping the leaving group is realized when the TP Trap temperature approaches the Tₘ. If the Tₘ is higher than T_{CL}, the leaving group can be removed without affecting the deposition rate.

In a preferred embodiment, leaving groups are effectively trapped if the TP trap is constructed with inert porous media with large surface area, such as porous quartz or ceramic. Alternatively, a reactive TP trap can be constructed. For example, when the leaving group is a halide, the halide free radical is reacted with a metal (e.g. copper, or zinc) at temperatures ranging from 250 to 300° C. The resulting metal halide can be recovered from the trap. In a preferred embodiment of the current invention, the trap is located between the deposition chamber and the pump to prevent reactions between intermediates. It is preferred and beneficial to build a drainage mechanism for cleaning the TP Trap when necessary. In this case, metal bromide can be removed from the trap by washing with acidic solution. The trap can then be rinsed with pure water and dried to recover its activity toward Bromine radical.

The Deposition Chamber Subsystem

All reaction products from the TP reactor (e.g. diradicals, or undesirable reaction products) enter the PM through a high conductance valve connected to the deposition chamber. The reaction products flow through an entrance hole on the top of the deposition chamber lid into the deposition chamber. To facilitate film deposition, a deposition chamber subsystem will preferably contain key components (e.g. a wafer holder, a guard ring, an pumping plate, an optional showerhead, and a chamber body to house the components).

A showerhead is an optional component. It is needed when the entrance hole for the gas reaction products is too close to the wafer holder. A showerhead is preferably located next to the entrance hole and inside the lid of the chamber. It is preferably a porous plate or solid plate with at least 500 holes that have at least 1 mm diameter. If a porous plate is used, the pore sizes should be at least 500 to 1000 um. The thickness of the showerhead should be 0.02 cm to 0.05 cm; but not thicker than 2-4 cm. Although not wanting to be bound by theory, when the gas entrance hole to the wafer distance, d is more than 0.6 to 1.2 times of the diameter of the wafer, a showerhead is not needed.

A wafer holder preferably consists of an electrostatic chuck (“ESC”) and a base plate. The ESC should provide sufficient static force to hold a 200 to 300 mm wafer that has at least 2 Torr, preferably 3.5 Torr of He backside pressure. Too little He behind the wafer could not provide sufficient heat conduction between the wafer and ESC, thus would result in wafer with much higher temperature than ESC and also poor temperature uniformity on wafer. A commercial available MFC (“mass flow controller”) can be used to control the He pressure and monitor the He leakage rate, in conjunction with a pressure monitor. To achieve high static forces under low temperatures, a special dielectric material is needed to manufacture the ESC. Since ESC holding force decreases with increases of electrical resistance of a ceramic medium that used to enclose the electrode in the ESC, ceramic medium with low resistivity (<10⁹ to 10¹⁰ Ω-m) is needed for the ESC of this invention. Special type of commercial dipolar ESC manufactured by TOTO, NTK and Kyocera are suitable for this invention. The dipolar ESC is operated at no more than +/−1000 V, preferably +/−600 V to be practically useful for this invention. The ESC is cooled by coolant passing through the inside of a base plate. Alternatively, low temperature can also be provided by thermoelectric cooling plate supplied by Dorsey Gate Inc. The base plate can be manufactured using thermally conductive material such as Aluminum, Stainless Steel or Titanium. Since Ceramic (e.g. Alumina) has low coefficient of thermal expansion (“CTE”), the base plate needs to have good thermal conductivity, and a low CTE to reduce the residual stress resulted from CTE mis-match. A chiller is used to circulate coolant through the base plate. The chiller should provide coolant temperatures as low as −35° C. to −70° C. The coolant should have low viscosity to be useful for this invention (e.g. Fluoro-Ethers from 3M). The chamber wall should be well insulated from the base plate of the ESC to avoid heat loss and condensation of water on the chamber wall.

A guard ring is useful to prevent backside wafer deposition. A front side guard ring can be manufactured from a thermally conductive material. The guard ring should not cover more than 2 mm++/−0.2 mm from the front edge of a wafer. The showerhead, guard ring and the deposition chamber need to be heated to temperatures that range from 10° C. to 30° C. (preferably 20° C. to 30° C.) above the ceiling temperature (“T_{CL}“) Of reactive intermediates to prevent film deposition on these components. Preferably, a backside guard ring is used to prevent backside deposition for this invention.

The wafer can be removed from the deposition chamber via shutting off the power to the ESC, lowering the ESC and supporting the wafer using three lifting pins. Alternately, the wafer can be removed from the deposition chamber by lifting the wafer up using lifting pins without moving ESC. A shutter mechanism has to be provided to close off the deposition chamber quickly during loading and unloading of a wafer to prevent moisture pick up from the wafer loading (i.e. load lock chamber), or unloading chamber. Both the load lock and the deposition chambers therefore have to be kept under vacuum of less than 1 mTorrs, preferably 0.2 mTorrs during wafer transfer. The chamber body can be constructed out of many particle free and dimensionally stable materials such as Aluminum, Stainless Steel, quartz, Pyrex glass or rigid plastics.

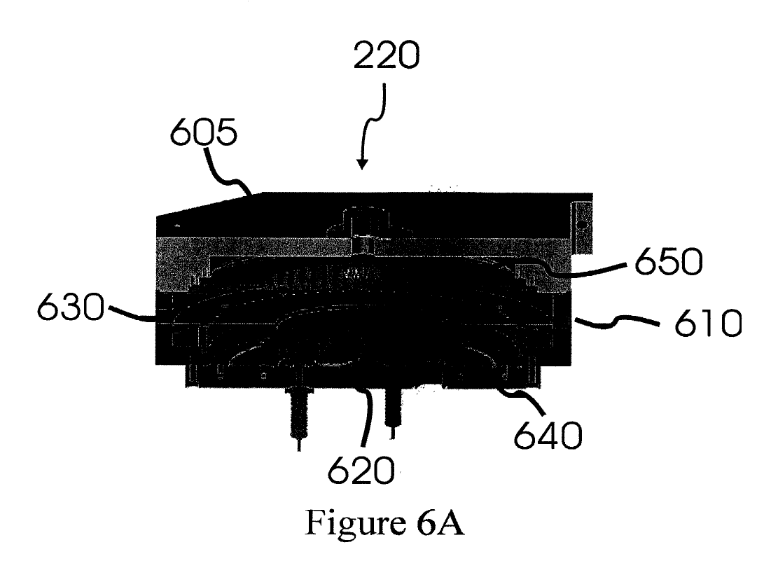

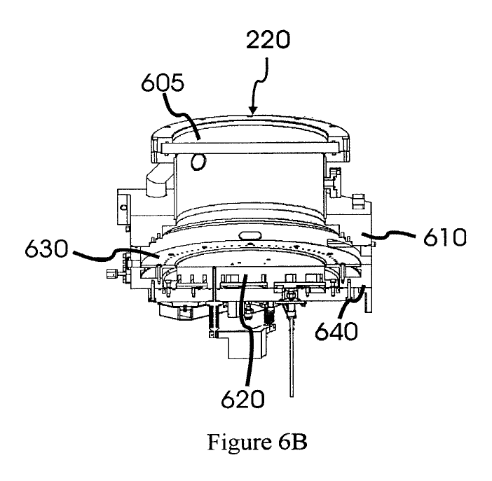

Design for the Deposition Chamber Subsystem. The preferred design for the deposition chamber subsystem (220) of this invention consists of six major parts as shown in FIG. 6A. The major parts comprise: a chamber lid 605, a chamber body 610, a electrostatic chuck 620, a pumping plate 630, a service plate 640 and an optional showerhead 650.

A showerhead (650) is mounted on the lid by spring-loaded screws. The preferred hole pattern will produce a uniform film on the wafer. The showerhead is preferably made of a transparent material (e.g. quartz) so that the wafer can be observed from outside the chamber lid. Although not wanting to be bound by theory, when the gas entrance hole to the wafer distance, (“d”) is more than 0.6 to 1.2 times of the diameter of the wafer, the showerhead is not needed.

The chamber lid (605), chamber body and service plate together form the vacuum envelope. This vacuum envelope should provide air leak rate that preferably less than 0.3 mTorr/min. As a preferred embodiment of the current invention, the chamber lid assembly consists of a lid, a gas manifold, and a NW40 quartz window. The gas manifold guides the incoming diradicals to the center of the deposition chamber. The lid assembly is heated passively by the chamber body. The quartz window is used to illuminate the wafer and to observe deposition and wafer transfer. Although not wanting to be bound by theory, when the distance from the entrance hole of the intermediates to the wafer is larger than the wafer diameter, concentration of intermediate above the wafer can be very uniform as a result of diffusion (Random walk of gasses), thus, the showerhead can be absent.

Therefore, in an preferred embodiment of this invention, the chamber lid consisting a tall cover as shown in the FIG. 6B is used. In FIG. 6B, the tall chamber cover is used to replace the flat chamber lid (605) shown in the FIG. 6A. The chamber cover (605A) shown in the FIG. 6B consists of a large Quartz window (606) that has a diameter of 300 mm.

In another preferred embodiment of the invention, a UV lamp can be mounted directly on the top of the Quartz window for pre-treatment of the wafer or before deposition of dielectric film. In this case, the need for an additional pre-treatment chamber can be avoided.

In a preferred embodiment, the chamber body is heated by several cartridge heaters inserted within its body and the temperature is controlled to within 30° C. to 40° C. of a desired temperature. The chamber body is also attached to a transfer module through a gate valve. A 0.75″ tall and 13″ wide slit opening is provided for wafer transfer in the Process Module.

The service plate is used to insulate the very cold ESC from the outside temperature and for installing the ESC. It is preferably constructed from very rigid material (e.g. 316 series stainless steel) to minimize deflection due to vacuum force. Alternatively, the service plate can be constructed of rigid plastic that has poor thermal conductivity. Thus, high modular plastic with low contamination such as Polyimide, Polyamide-imide and Polyetherketone are preferred.

The electrostatic chuck (“ESC”) assembly consists of the bipolar Electrical Chuck, three lift pins, bellows, and a backside helium line. In a preferred embodiment, the ESC is mounted to the service plate with seven O-rings: one large O-ring (8″ ID) for ESC sealing; three 0.53″ ID O-rings for the lift pins; two 0.46″ ID O-rings for helium feed through and thermal couple feed through, and one 1.33″ ID O-ring for the two ESC electrodes. The three lift pins and bellows are attached to the service plate. The ESC is constructed of a monolith titanium alloy. The titanium alloy has low weight density and has low coefficient of thermal expansion (“CTE”). A differentially pumped O-ring is located between ESC and service plate to reduce the risk of a possible leak. Although not wanting to be bound by theory, the thermal mismatch between ESC and service plate during operation is minimized by the similar total thermal expansion of titanium (8.4 10⁻⁶* [ΔT of 60° C.]=5.0⁻⁴ inch/inch) and stainless steel (18.8 10⁻⁶* [[ΔT of 25° C.]=4.7⁻⁴ inch/inch). Titanium is a poor thermal conductor relative to aluminum and aluminum nitride (only 0.22W/cm/C for Titanium). The ESC design minimizes the surface contact area with service plate. There is no convection heat transfer between ESC and PM due to the differential pumping. Additionally, two embedded electrodes below the ESC surface are utilized to hold the wafer in place. The bi-polar ESC design has a maximum of +/−1000V on each electrode, wherein each electrode attracts opposite charge inside wafer to the wafer surface next to the electrode. The attraction force provides the holding force necessary to hold up to 7 Torr of He between the wafer and ESC.

In a preferred embodiment of the current invention, a helium line is attached to the service plate and a pressure sensor assembly. The pressure sensor assembly consists of a 100 mTorr Baratron™ (capacitance manometer made by MKS Instrument) and thermal pressure gauge. The thermal pressure gauge is capable of measuring a wide range of pressure (1 to 1000 Torr). The Baratron™ measurement is accurate to 0.15% of the full scale (0.15 mT) and is used for accurate process pressure monitoring. It is heated to around 40° C. to prevent film deposition. A ½″ stainless steel pneumatic valve is located between the pressure gauge and deposition chamber to prevent high-pressure exposure during venting and high-pressure operation (>2 Torr). This valve is mainly to maintain the measurement accuracy of the Baratron™ pressure sensor assembly. The valve is interlocked with a high pressure gauge so that it cannot be opened if the chamber pressure is higher than 2 Torrs. He gas transfers heat between wafer and ESC and provides wafer cooling. ESC backside pressure should be at least 2, preferably 3 Torrs of He. He leak rate should be less than 0.5 sccm at +/−600V ESC voltage. A special device that has both a MFC and a pressure gauge does the helium pressure control.

The pumping plate serves several purposes. For example, the pumping plate can be used to center or guide the wafer; provide uniform pumping; and reduce deposition on ESC and the backside of the wafer. In a preferred embodiment, the top of the pumping plate is positioned about 0.20″ above wafer surface. The central opening for accepting wafers onto ESC is beveled steeply. Wafers that are positioned slightly off center (e.g. <±50 mils, or ±1.25 mm) during wafer transfer will be centered by the bevel. However, the centering capability only serves as an insurance measure, since it also has the potential to create particles. Wafer centering should be completed during robot arm calibration. The preferred embodiment of the pumping plate has a uniform distribution of small pumping holes. These small holes lead to a large pumping channel between pumping plate and chamber body. The large flow conductance ratio of pumping channel to pumping holes creates a uniform pumping rate around wafer. The cross section area ratio of the high conductance channel to each pumping hole is about 140.

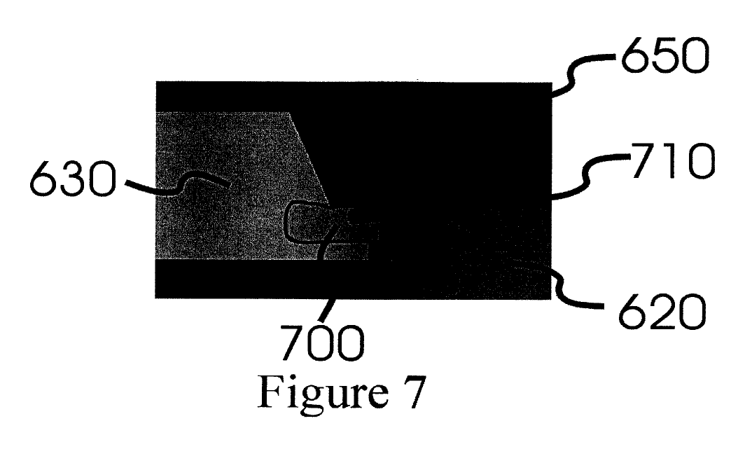

A close up view of the pumping plate 630, the ESC 620, the wafer 710, and the guard ring 700 is illustrated in FIG. 7. When the guard ring is absent, a small gap exists between the ESC and pumping plate. The position and shape of the gap limited, but did not eliminate the diffusion of reactive intermediate material to the backside of the wafer 710. Thus, to avoid the deposition of polymer film to the backside of the wafer during Transport Polymerization, a backside guard ring 700 is utilized.

Pre- and Post-Treatment Chamber (“PTC”)

A pre-treatment chamber is a component for process modules (“PM”) of this invention. The primary objective for pre-treatment of a wafer before film deposition is to assure that the wafer surface is void of contaminants (e.g. low molecular-weight materials, or small molecules) that may have adsorbed onto the wafer. The removal process is completed by exposing the wafer to short wavelengths of ultraviolet (“UV”) radiation that ranges from 170 nm to 450 nm, wherein the preferred range is from 220 nm to 350 nm. Exposure of the wafer in a pre-treatment chamber under the UV conditions and under vacuum for specified time-period was adequate to remove contaminants.

In a preferred embodiment of the present invention, a UV lamp with a housing and UV light power supply with a controller are needed for pretreatment. A pulse from the UV lamp can supply a sufficient pulse of energy in a range that is greater than 100 to 400 W/cm² of UV is preferred. A commercial UV pulse lamp can be obtained from the Xenon Corporation (20 Commerce Way, Woburn, Mass.).

In one preferred embodiment of the present invention, the pretreatment is performed on the top of the deposition chamber, which is facilitated with the quartz window as shown in the FIG. 6B. A 300 mm diameter quartz window made of pure quartz single crystal and has about 1 to 1.5 inch thickness can be used for this purpose. The quartz or sapphire window allows UV to pass through and is thick enough to stand the vacuum pressure (1.0″ thick, 14″ diameter). A clamp locates and provides down pressure to the quartz window through an O-ring mounted inside the clamp. When pre-treatment is performed on the top of the deposition chamber, a wafer is supported by three lifting pins or directly on the ESC. Alternatively, the pretreatment can be performed on the top of a post-treatment chamber.

In a preferred embodiment of the current invention, after the film deposition occurs, the wafer is removed from the deposition chamber and transfer to a post-treatment chamber. The post-treatment chamber can also double as a pre-treatment chamber. The post-treatment occurs after film deposition. It is used to eliminate all unpaired electron trapped in the film and increase the crystallinity of the as-deposited film. The films produced by the current invention are formed in vacuum by step polymerization of many intermediate molecules or intermediates called diradicals. Each diradical carries an unpaired electron on both ends of the intermediate. We call the diradical as an intermediate, because it is very reactive toward another diradical. It has a lifetime in 10⁻⁶ second or less, when colliding at solid state with another diradical, even at temperatures as low as −100° C. Step polymerization, as the name implies, is a reaction for polymer-chain extension that occurs one step a time. Theoretically each diradical can grow a polymer from both ends of the reactive intermediate, and after each step of the reaction, the polymer theoretically leaves an unpaired electron at each of the polymer chain ends.

A polymer chain created by step polymerization can continue to grow as long as no free radical scavenger is present, or until the chain end becomes physically buried under other polymer chains. Because free radical scavenger are absence under a vacuum, the resulting polymer films comprise unpaired electrons at polymer chain ends, and the ends can still be reactive toward free radical scavengers. Typical free radical scavengers are compounds that comprise an X—H group or oxygen (wherein X comprises Nitrogen, Sulfur or Oxygen). Such compounds are very reactive toward the polymer film's unpaired electrons, and can terminate the polymer chain growth. It is important to note that smaller molecular size free radical scavengers are needed in order to diffuse to the chain ends that are buried under other polymer chains.

The formation of reactive polymer ends with free radical scavengers form reaction products that carry thermally unstable groups (e.g. —C═O or C—X (wherein, X=O, N, S)). Unfortunately, these thermally unstable groups decompose at temperatures from 250° C. to 400° C. in only a few minutes. In addition, presence of these unpaired electrons at polymer chain ends can result in poor electrical properties. The above problems pose a significant challenge to make chemically and electrically stable polymer films when the as-deposited film is exposed to air before the reactive polymer ends are converted to stable chemical groups. One possible solution to stabilize the reactive polymer ends is by a method of thermal annealing of the as-deposited film with hydrogen gas under high temperature before the film is exposed to air. This annealing process can achieve both high crystallinity for better dimensional stability and chemical stability by capping all unpaired chain ends with C—H bond, which are more stable than C═O or C—X (wherein, X=O, N, S) groups. In addition, post-treatment of as-deposited films at high temperature will also increase the crystallinity of the films.

Preferred Design for UV Lamp

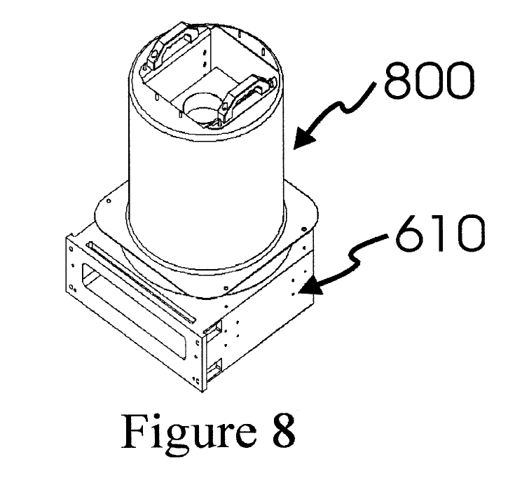

In a preferred embodiment of the current invention, the UV lamp comprises an 8 to 10″ diameter spiral, ozone free Xenon gas lamp manufactured by Xenon Corporation at Woburn, Mass. The Xenon lamp is mounted in a lamp housing assembly. The lamp housing assembly comprises a vent screen and two electrical cables to be mounted to the UV power supply. A reflector designed to optimize UV light uniformity and make sure of all UV lights leaving the lamp housing in parallel is also includes. The RX-747 pulsed UV system has an integrated power supplier capable of providing 2 kW of UV (220 nm to 350 nm) at 10 Hz pulse. It uses single phase 180-264 VAC, 50/60 Hz, 18A power. A cooling system avoids the lamp from burning out. A 4-inch diameter duct is attached to the lamp housing and fastened to a blower and filter unit. The blower provides at least 500 cubic feet per minute (“CFM”) of airflow. The UV housing 800 can be mounted on the top of a pretreatment chamber, a post treatment chamber, or preferably the deposition chamber 610, as shown in the below in FIG. 8.

The Post-Treatment Chamber:

In a preferred embodiment of the current invention, the post-treatment chamber serves three main functions (i.e. to provide additional storage slots in the process module; to eliminate free radicals on polymer ends; and to serves as an alternative port to mount an UV housing for pretreatment. For example, the storage can greatly enhance wafer throughput and eliminate the 2-wafer-load-lock as a bottleneck in the production process. Free radical ends that are trapped in films can be converted to stable products without exposing the films to air.

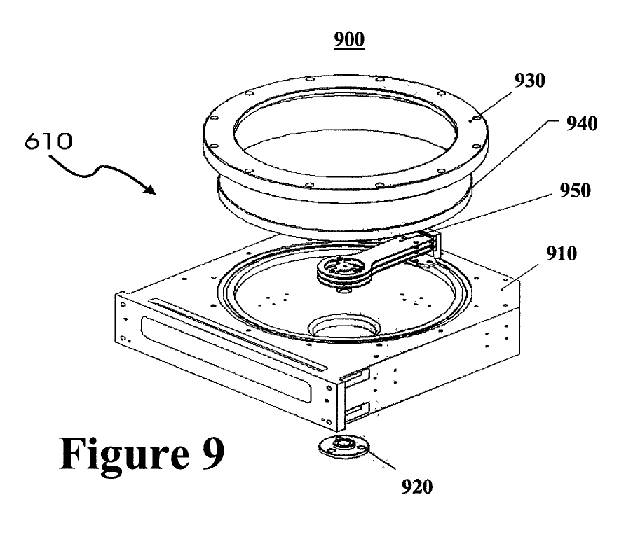

A preferred embodiment of the current invention includes a post-treatment chamber (FIG. 9, showing detail of 610 in FIG. 8 and that 800 is a UV lamp), which comprises of the following 5 parts:

The chamber body 910, is made of single piece aluminum with two Dowel pins (0.393″ diameter, <0.45″ extruded above surface) attached at its mounting surface. The body is mounted to Transfer Module (“TM”) through 4 screws and washers (M8, 25 mm-30 mm long).

The pressure release plug 920 is a safety feature needed in case the pressure inside the pretreatment module (“PT”) exceeds the atmospheric pressure. This plug is mounted to PT body through 3 shoulder screws and 3 compression springs The O-ring used is a 0.8” ID Viton O-ring.

The clamp 930 is mounted to the PT body through 12×¼″-20, 1-⅝″ long socket head screws.

The quartz window 940 allows UV to pass through and is thick enough to stand the vacuum pressure (1.0″ thick, 14″ diameter). The clamp locates and pressure down the quartz window through an O-ring (DSI P/N 30-00019) mounted inside the clamp.

The wafer support sub-assembly 950 holds 3 wafers (the bottom slot may not be accessible due to software limitation at present time). It can be mounted through the PT top opening. See more details in the next sections.

Vacuum Pumping System

In a preferred embodiment of the present invention, the pumping system comprises a gate valve, a throttle valve, a chamber by-pass valve, the turbo pump, the mechanical pump and an optional cold trap at −80° C. The gate valve isolates the chamber from vacuum pump. The throttle valve varies the pumping speed during processing and provides maximum pumping speed during PM pumping down and during wafer exchanges. The chamber by-pass valve provides slow pumping rate during initial PM pumping down or after opening PM. The pumping speed is adjustable by a needle valve. The turbo pump is mounted below the throttle valve. It provides high pumping rate at low PM pressure. The manual speed setting on the turbo pump controller is typically set at normal speed (approx. 50,000 RPM). The turbo can be turned on from the PM control screen. A mechanical pump is used to backup the turbo pump. The pressure gauge measures the pressure at the mechanical pump. The mechanical pumping is connected to the exhaust system in the customer's facility. The pump is turned on and off manually in the remote electrical panel. The optional cold trap can catch organic residuals that pass through the deposition chamber. The cold trap is kept at temperatures lower than −50° C., preferably −60° C. to prevent pump from contamination by organic residuals. Commercial mechanical chillers are available for this purpose. The cold trap is in fluid communication with a dry pump. The pump should provide at least 20 to 30 ft³/minute of pumping rate to be useful for this invention.

Application of the PM of this Invention:

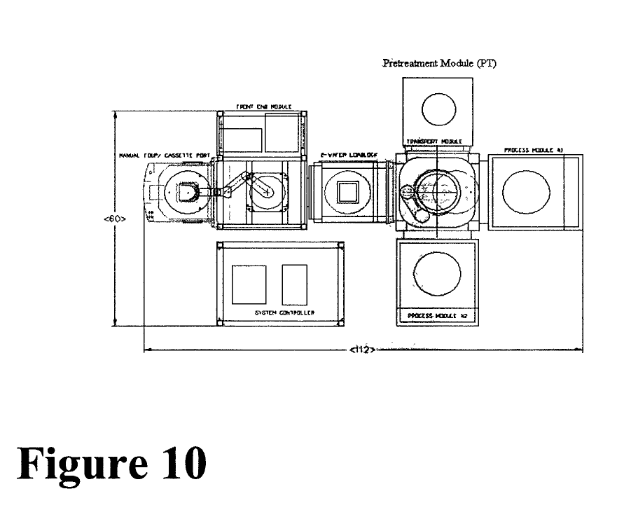

To use the PM for the deposition of dielectric film, the PM needs to be incorporated with other functional components that are illustrated in a schematic drawing of FIG. 10. The FIG. 9 shows a pilot production system consists of a Transfer Module (“TM”) with a 2 PM and one Post-Treatment chamber (“PT”). The step-by-step wafer flow is shown in the FIG. 10 and is described as follows:

An ATM Robot (“AR”) will pick a wafer from a pre-selected slot of Loadport (“LP”) (a cassette for manual systems) and place it into Atmospheric Pre-aligner (“AP”). The Atmospheric Pre-aligner determines the center and orientation of the wafer, and it centers the wafer and aligns the notch to a previously set user-programmable angle.

The ATM Robot will pick the wafer from Atmospheric Pre-aligner and place the wafer into Dual Wafer Load Lock (“DWLL”). Dual Wafer Load Lock door will be closed. Dual Wafer Load Lock will be pumped down to a pre-specified base-pressure. Vacuum Transport Module (“VTM”) door will be opened.

Vacuum Robot will pick the wafer from Dual Wafer Load Lock and place it into Pre-Treatment Module (“PTM”). Vacuum Transport Module door will be closed. Wafer will complete the pre-treatment process in Pre-Treatment Module for a pre-programmed period of time. Process Module (“PM”) door will be opened.

Vacuum Robot (“VR”) will pick the wafer from Pre-Treatment Module and place it into a Process Module. Process Module door will be closed. Deposition will take place in Process Module according to the recipe steps in the selected process recipe. Process Module door will be opened after the deposition process is completed. Vacuum Transport Module door will be opened.

Vacuum Robot will pick the wafer from Process Module and place it into Dual Wafer Load Lock. Process Module door will be closed. Vacuum Transport Module door will be closed. Dual Wafer Load Lock will vent to atmospheric pressure. Dual Wafer Load Lock door will open.

To complete a cycle, ATM Robot will pick the wafer from Dual Wafer Load Lock and place it back to the pre-selected slot that it was from originally.

Operational Procedures Using PM of this Invention:

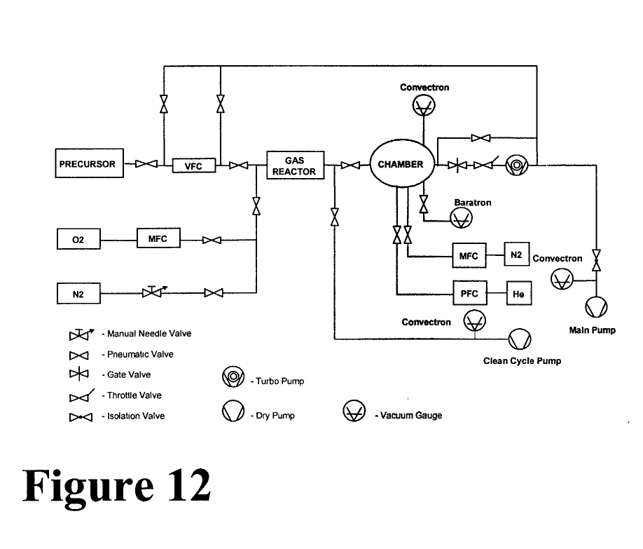

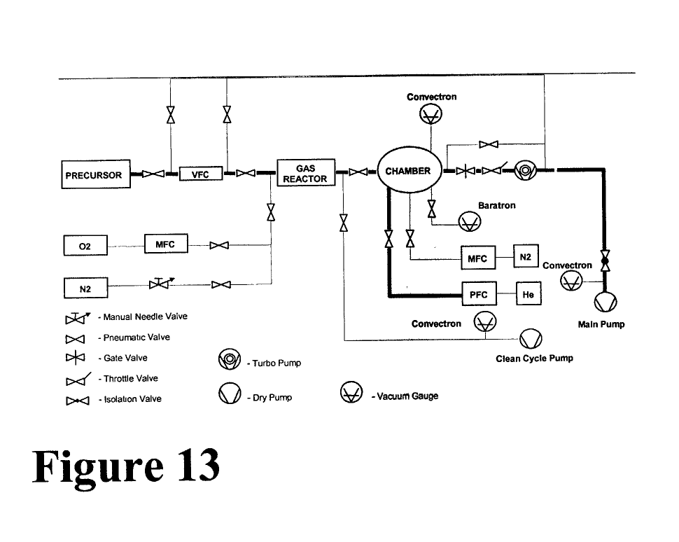

The schematic in FIG. 12 shows a PM process control flow diagram with all of the major components for the PM process control. FIG. 13 shows highlighted flow paths for gas flow during the wafer deposition process. During the deposition process, precursor vapor flows through Vapor Flow Controller (“VFC”) to create programmed flow rate. The precursor vapor is then broken down in TP reactor into intermediate and by products. The intermediate is deposited onto wafer to create the low-K film. Excess intermediate, if any, and by products are pumped through turbo pump. All exhaust gas will be pumped through a main pump and will be burnt in a facility scrubber.

The helium is controlled by Pressure Flow Controller (“PFC”) to provide a blanket of helium between wafer and electrostatic chuck (“ESC”) in the chamber. The blanket of helium keeps wafer temperature uniform and close to the chuck temperature. The chuck is cooled down by a chiller to −30° C. to −40° C.

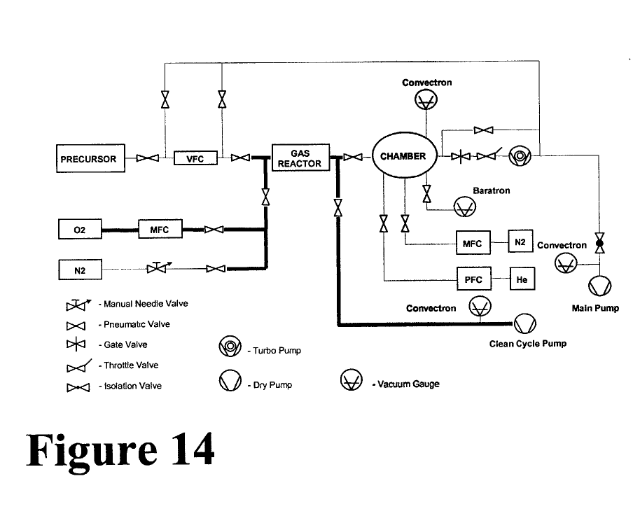

The FIG. 14 shows highlighted flow paths of oxygen clean flow after wafer process as follows: oxygen flows through Mass Flow Controller (“MFC”) for predefined rate. The O₂ flows through TP reactor to clean any carbon residual to form CO₂. The CO₂ and O₂ are then pumped through Clean Cycle Pump. This path is isolated from chamber to avoid O₂ contamination.

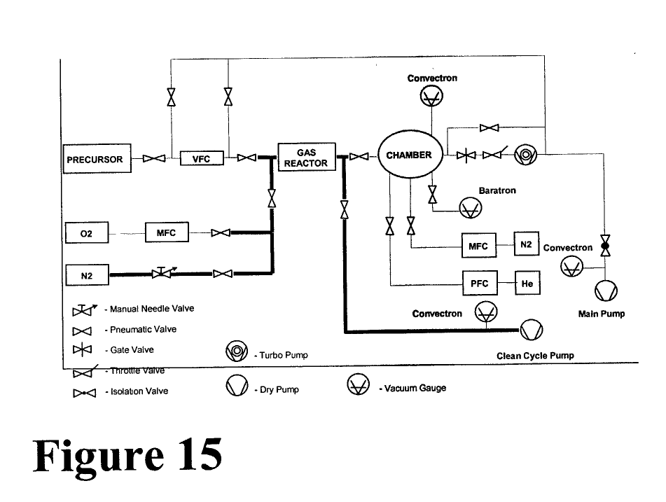

The FIG. 15 shows highlighted flow paths of N₂ purge flow after O₂ cleaning process. This path purges O₂ from the system to eliminate contamination.

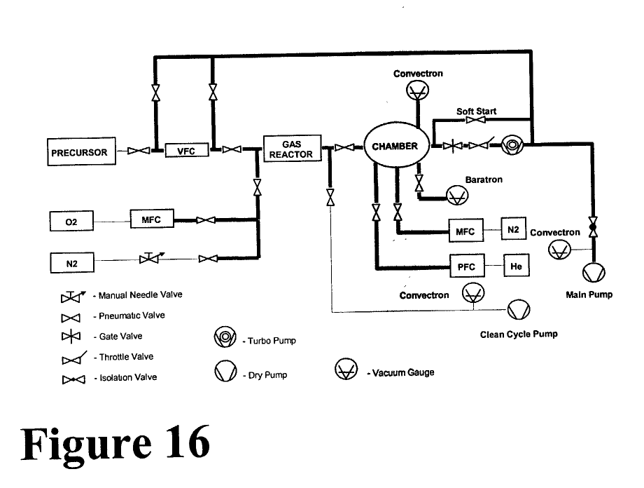

The FIG. 16 shows the highlighted flow paths for PM pump down. Although the path to Clean Cycle Pump is not highlighted, it is always under vacuum. If the chamber is under baseline vacuum, gate valve, throttle valve, and software valve should be close when pumping down other paths to void back stream to chamber.

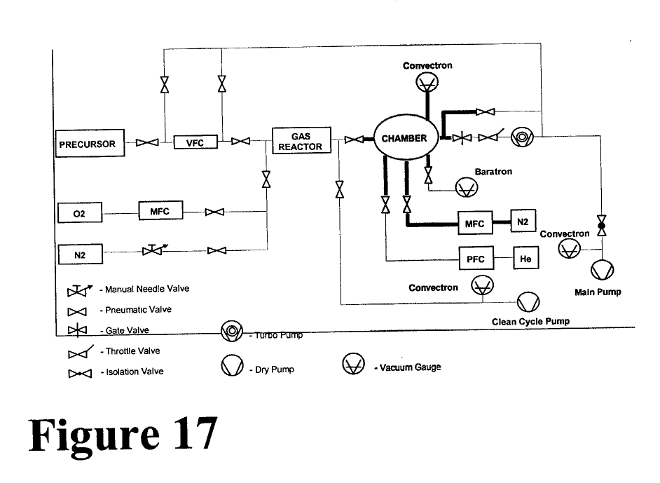

The FIG. 17 shows the PM chamber vent to atmosphere flow schematic. Highlighted flow paths are for vent to atmosphere. The purpose of vent to atmosphere is for chamber service.

It should be appreciated by those of ordinary skill in the art that other embodiments may incorporate the concepts, methods, precursors, polymers, films, and devices of the above description and examples. The description and examples contained herein are not intended to limit the scope of the invention, but are included for illustration purposes only. It is to be understood that other embodiments of the invention can be developed and fall within the spirit and scope of the invention and claims. For example, some of the above discussions presented a single reactor per one deposition chamber; however, those who are skillful in tool designs can easily apply the above principles to make a larger reactor for industrial cluster tools that have multi-deposition chambers.

### REFERENCES CITED

The following U.S. Patent documents and publications are incorporated by reference herein.

### U.S. Patent Documents

U.S. Pat. No. 3,268,599 issued in August of 1966 with Chow et al. listed as inventors.

U.S. Pat. No. 3,274,267 issued in September of 1966 with Chow listed as inventors.

U.S. Pat. No. 3,342,754 issued in September of 1967 with Gorham listed as inventors.

U.S. Pat. No. 5,268,202 issued in December of 1993 with You et al. listed as inventors.

U.S. Pat. No. 6,140,456 issued in October of 2000 with Foggiator et al. listed as inventors.

U.S. patent application Ser. No. 09/925,712 filed in August of 2001 Lee et al. listed as inventors.

U.S. patent application Ser. No. 10/029,373 filed in December of 2001 Lee et al. listed as inventors.

U.S. Patent application Ser. No. 10/028,198 filed in December of 2001 Lee et al. listed as inventors.

### Other References

Brun A. E. 100 nm: The Undiscovered Country, Semiconductor International, p79, February 2000

Kudo et al., Proc. 3d Int. DUMIC Conference, 85-92 1997

Wary et al., Semiconductor International, p211-216 1996

LaBelle et al., Proc, 3d Int. DUMIC Conference, 98-105 1997

Geissman T. A. Principles of Organic Chemistry, 3rd edition, W. H. Freeman & Company, p275

Lee, J., et al. Macromol Sci-Rev. Macromol. Chem., C16(1) 1977-78.

Wunderlich et al. J. Polym. Sci. Polym. Phys. Ed., Vol. 11, 1973.

Wunderlich et al., J. Polym. Sci. Polym. Phys. Ed., Vol. 13 1975.

Wunderlich, macromolecular physics, vol. 1-2, 1976.

What is claimed:

1. A process module for transport-polymerization (“TP”) of a precursor comprising:
(a) a material delivery subsystem adapted to deliver the precursor to a TP reactor;
(b) the TP reactor adapted to receive the precursor and to generate an intermediate;
(c) a deposition chamber designed to produce a polymer film onto a substrate under a vacuum; and
(d) a substrate pre- and post-treatment chamber designed to remove contamination from the substrate and stabilize the polymer film on the substrate under the vacuum.

2. The process modules of claim 1, further comprising a pump cold-trap in fluid communication with the deposition chamber to prevent organic residuals from passing from the deposition chamber into a pump system.

3. The process module of claim 2, wherein the cold trap is at a temperature below −50° C. during the precursor deposition.

4. The process modules of claim 1, further comprising a pump system in fluid communication with a pump cold-trap to provide the vacuum for the deposition chamber.

5. The process modules of claim 1, further comprising a reactor cleaning subsystem mounted to the TP reactor to purge the reactor of organic residues.

6. The process module of claim 1, further comprising a TP trap, interposing the TP reactor and the deposition chamber, and adapted to confine undesirable chemicals generated in the TP reactor.

7. The process module of claim 6, wherein the TP Trap contains porous quartz and is maintains a temperature that is at least 10° C. higher than a ceiling temperature (“T_{cl}”) of reactive intermediates that are generated from the TP Reactor.

8. The process module of claim 6, wherein the TP Trap comprises reactive metal turnings that are kept at a temperature ranging from 200° C. to 450° C.

9. The process module of claim 6, wherein the TP Trap comprises reactive metal turnings that are kept at a temperature ranging from 300° C. to 350° C.

10. The process module of claim 9, wherein the reactive metal turnings are copper or zinc.

11. The process modules of claim 1, wherein the precursor has the following general chemical structure: 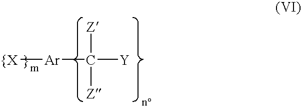
wherein, n° or m are individually zero or an integer, and (n°+m) comprises an integer of at least 2 but no more than a total number of sp²C—X substitution on the aromatic-group-moiety (“Ar”),
Ar is an aromatic or a fluorinated-aromatic group moiety,
Z′ and Z″ are similar or different, and individually a hydrogen, a fluorine, an alkyl group, a fluorinated alkyl group, a phenyl group or a fluorinated phenyl group;
X is a leaving group, and individually a —COOH, —I, —NR₂, —N⁺R₃, —SR, —SO₂R, wherein R is an alkyl, a fluorinated alkyl, aromatic or fluorinated aromatic group, and
Y is a leaving group, and individually a —Cl, —Br, —I, —NR₂, —N⁺R₃, —SR, —SO₂R, or —OR, wherein R is an alkyl, a fluorinated alkyl, aromatic or fluorinated aromatic group

12. The process module of claim 11, wherein a bonding energy between the leaving group (“(BE)_{L}”) and a core group of the precursor comprises a value less than 75 Kcal/Mole, and the range of the (BE)_{L} comprises a range of 20 to 45 Kcal/Mole lower than a bonding energy of a next weakest chemical bond energy (“(BE)_{c}”) present in the precursor.

13. The process module of claim 1, wherein the material delivery subsystem comprises:
(a) a sample container for holding the precursor;
(b) a heater to vaporize the precursor; and
(c) a feed control component to regulate the flow rate of the vaporized precursor.

14. The process module of claim 13, wherein the sample container comprises a non-corrosive material that can be heated from room temperature to 150° C.; and can withstand the vacuum.

15. The process module of claim 14, wherein the non-corrosive material comprises pyrex glass, stainless steel, or ceramic quartz.

16. The process module of claim 13, wherein the feed control component comprises a liquid mass flow controller (“LMFC”) or a vapor flow controller (“VFC”).

17. The process module of claim 16, wherein the LMFC delivers precursors at a rate in a range of 0.5 to 10 g/hour to a wafer,

18. The process module of claim 17, wherein the rate of precursors delivery to a 200 mm wafer is in a range of 1.0 to 5 g/hour, and the rate of precursor delivery to a 300 mm is in a range of 2 to 10 g/hour.

19. The process module of claim 16, wherein the VFC delivers about 2 to 10 standard cubic centimeters per minute (“sccm”) of precursors to a 200 mm wafer.

20. The process module of claim 1, wherein the TP reactor is in fluid communication with the material delivery subsystem and the TP reactor comprises:
(a) a gas inlet for receiving precursor material from the material delivery subsystem;
(b) a thermal source for cracking precursor material;
(c) a heater body for transferring heat to the precursor material;
(d) a thermal couple to regulate the temperature of the thermal source and precursor material;
(e) a heating shield in contact with the heater body;
(f) an insulation container surrounding the TP reactor; and
(g) a gas outlet for discharging intermediates from the TP reactor.

21. The process module of claim 20, wherein the thermal source comprises an infra red (“IR”) heater.

22. The process module of claim 20, wherein the thermal source is derived from an irradiation heater, a thermal heater, plasma or microwave.

23. The process module of claim 20, wherein a wall of the heater body is manufactured from an IR transparent material and has inside heater elements.

24. The process module of claim 23, wherein the IR transparent material is quartz or Pyrex glass.

25. The process module of claim 23, wherein the heating elements can adsorb sufficient IR radiation to achieve uniform temperatures that range from 300° C. to 700° C.

26. The process module of claim 23, wherein the heating elements can adsorb sufficient IR radiation to achieve uniform temperatures that range from 450° C. to 600° C.

27. The process module of claim 20, wherein the heater body comprises a plurality of alternating heating paths and mixing gaps.

28. The process module of claim 27, wherein the heating paths have a spiral orientation.

29. The process module of claim 27, wherein the heating paths comprise multiple heating fins to increase the heating efficiency.

30. The process module of claim 29, wherein the multiple heating fins are spaced at a distance less than the mean free path (“MFP”) of a gas in the heating region.

31. The process module of claim 20, wherein the heater body comprises a plurality of rows and columns of alternating heater fins.

32. The process module of claim 31, wherein the plurality of rows and columns of alternating heater fins are spaced at a distance less than the mean free path (“MFP”) of a gas in the heating region.

33. The process module of claim 20, wherein the heater body comprises closely packed spherical balls.

34. The process module of claim 33, wherein the spherical balls comprise a diameter that ranges from 0.01 mm to 10 mm.

35. The process module of claim 33, wherein the spherical balls are constructed from materials selected from a group consisting of ceramic, silicon carbide, and alumina carbide.

36. The process module of claim 20, wherein the heater body consists of a plurality of alternating heating elements and a mixing zones, wherein the heating elements on a standoff of the heater body are arranged in a spiral configuration relative to a direction of overall flow from gaseous precursors in the TP Reactor.

37. The process module of claim 36, wherein the plurality of alternating heating elements consists of porous ceramic disks.

38. The process module of claim 36, wherein the plurality of alternating heating element consists of ceramic disks with small holes.

39. The process module of claim 36, wherein the plurality of alternating heating element consist of plurality of ceramic fins.

40. The process module of claim 20, wherein the heater body is heated to a temperature of at least 400° C. but no more than 680° C.

41. The process module of claim 20, wherein the heating shield is closely contacted with standoffs of the heater body, and is insulated from the insulation container of the TP reactor by a vacuum gap of at least 300 μm.

42. The process module of claim 20, wherein the heating shield is heated to a temperature of at least 300° C., but is less than the temperature of the heater body.

43. The process module of claim 1, wherein the deposition chamber comprises:
(a) a chamber lid assembly that forms a first part of a vacuum envelope;
(b) a chamber body that forms a second part of the vacuum envelope;
(c) a substrate-holder adapted to hold the substrate material;
(d) a pumping plate adapted to center the substrate on the substrate-holder and to provide pumping; and
(e) a service plate that forms a third part of the vacuum envelope.

44. The process module of claim 43, wherein the chamber lid assembly comprises:
(a) a lid heated passively by the chamber body;
(b) a gas manifold to guide incoming materials into the deposition chamber; and
(c) at least one observation window.

45. The process module of claim 44, wherein the gas manifold directs incoming gas reaction products from reactor to the deposition chamber.

46. The process module of claim 44, wherein the observation window is used to illuminate the substrate with UV.

47. The process module of claim 44, wherein the observation window is quartz.

48. The process module of claim 42, wherein the chamber body comprises a chamber wherein an environment for film deposition can be maintained.

49. The process module of claim 42, wherein the chamber body further comprises a cartridge heater inserted within the chamber body and a heated path to direct incoming gas reaction products from reactor to the deposition chamber.

50. The process module of claim 42, further comprising a showerhead.

51. The process module of claim 42, wherein the substrate holder comprises an electrostatic chuck (“ECS”).

52. The process module of claim 51, wherein the electrostatic chuck (“ECS”) provides a static force capable of holding a 300 mm wafer with at least 1 Torr of a backside pressure from helium.

53. The process module of claim 52, wherein the backside pressure has a leak rate that is less than 0.4 standard cubic centimeters per minute (“sccm”).

54. The process module of claim 52, wherein the backside pressure has a leak rate that is 0.2 standard cubic centimeters per minute (“sccm”).

55. The process module of claim 52, wherein the helium is at a temperature as low as −50° C.

56. The process module of claim 1, wherein a lid of the substrate pre- and post-treatment chamber has a quartz window in the rage of 200 mm to 300 mm in diameter.

57. The process module of claim 56, wherein the quartz widow provides at least 70% transmission of UV light.

58. The process module of claim 57, wherein the UV light has a wavelength in a range of 200 nm to 450 nm.

59. A method of using the process module of claim 1 to produce a stabilized polymer film onto a substrate comprising:
(a) loading the substrate into the pre-treatment chamber;
(b) creating a vacuum inside the pre-treatment chamber;
(c) exposing the substrate to UV light, forming a V-treated-substrate under the vacuum;
(d) transferring the UV-treated-substrate to the deposition chamber under the vacuum;
(e) applying voltage to the UV-treated-substrate under the vacuum;
(f) introducing a precursor from the TP reactor into the deposition chamber under the vacuum;
(g) depositing a polymer film on the UV-treated-substrate, forming an as-deposited-substrate under the vacuum; and
(h) heating the as-deposited-substrate in the post-treatment chamber under an atmosphere to form the stabilized polymer film.

60. The method of claim 59, whereby exposing the substrate to ultra violet (“UV”) light requires maintaining an intensity of greater than 140 mWatts of power for at least 10 seconds.

61. The method of claim 59, whereby the vacuum is below 1 mTorrs.

62. The method of claim 59, whereby the vacuum is about 0.01 mTorrs.

63. The method of claim 59, whereby heating the as-deposited-substrate occurs in a temperature range from 350° C. to 450° C.

64. The method of claim 59, wherein heating the as-deposited-substrate occurs in an atmosphere containing hydrogen in argon that is below 2 Torrs of chamber pressure.

65. The method of claim 64, wherein heating the as-deposited-substrate occurs in an atmosphere containing about 5 to 10% volume of hydrogen in argon.

66. A method for cleaning a deactivated reactor having an organic residue comprising:
(a) oxidizing the organic residues inside the deactivated reactor; and
(b) purging the TP reactor with a gas.

67. The method of claim 66, wherein the gas is nitrogen.
